(19) United States
(12) Patent Application Publication
(10) Pub. No.: US 2008/0168215 A1
(43) Pub. Date: Jul. 10, 2008

(54) Storing Information in a Memory

(76) Inventors: Anxiao Jiang, College Station, TX (US); Vasken Z. Bohossian, Montreal (CA); Jehoshua Bruck, La Canada, CA (US)

Correspondence Address: FISH & RICHARDSON P.C., P.O. BOX 1022, MINNEAPOLIS, MN, 55440-1022, US

(21) Appl. No.: 11/969,838

(22) Filed: Jan. 4, 2008

Related U.S. Application Data
(60) Provisional application No. 60/878,961, filed on Jan. 5, 2007.

(51) Int. Cl. G06F 12/02; G11C 16/10

(52) U.S. Cl. 711/103; 365/185.03; 711/E12.008

(57) ABSTRACT

Systems and methods, including computer software products, can be implemented for updating or modifying stored data. Multiple variables are represented by one or more cell values in a memory. Each variable is associated with one or more of the cell values and at least one single cell value influences a value of at least two of the variables. Multiple states of the multiple variables are defined. At least one of the multiple defined states of the multiple variables is associated with more than one set of cell values.

### CROSS-REFERENCE TO RELATED APPLICATIONS

This application is related to and claims the benefit of co-pending provisional application Ser. No. 60/878,961, filed Jan. 5, 2007, which is incorporated herein by reference.

### BACKGROUND

This disclosure relates to storing information in a memory. Some memories include storage cells that transit asymmetrically among states. For example, flash memories may store information in the states of floating-gate cells. The state of a floating-gate cell may depend on the amount of charge trapped in the cell, and writing information to a flash memory may include injecting charge into one or more of the floating-gate cells (e.g. by the hot-electron injection mechanism or the Fowler-Nordheim tunneling mechanism). Rewriting information to the flash memory may include erasing all of the information stored in a plurality (e.g. a block) of floating-gate cells.

### SUMMARY

This specification describes technologies relating to storing information in a memory.

In one general aspect, multiple variables are represented with one or more cell values in a memory. Each variable is associated with one or more of the cell values, and at least one single cell value influences a value of at least two of the variables. Multiple states of the multiple variables may be defined, and at least one of the multiple states of the multiple variables is associated with more than one set of cell values.

Implementations can include one or more of the following features. Multiple first cell values may be written to multiple cells of the memory, and each of the cells can include multiple possible cell states sequentially ordered from a lowest cell state to a highest cell state. Each of the first cell values corresponds to one of the multiple possible cell states, and at least one of the first cell values corresponds to a cell state other than the lowest cell state. The first cell values jointly represent first store values of the multiple variables, and at least one of the first cell values includes an individual cell value that is based at least in part on the first store values of more than one of the multiple variables. Multiple second cell values may be written to the cells, and each of the second cell values corresponds to one of possible cell states. Each of the cells of the memory either remains in its previous cell state or progresses to a cell state higher than its previous cell state.

Each of the cells of the memory may have two possible cell states, and each of the first cell values and each of the second cell values correspond to one of the two possible cell states. In some implementations, each of the cells may have three or more possible cell states, and each of the first cell values and each of the second cell values correspond to one of the three or more possible cell states. The second cell values can jointly represent second store values of the multiple variables, and the second store value for one or more of the multiple variables differs from the first store value for the variable. At least one of the second cell values can be an individual cell value based at least in part on the second store values of more than one of the multiple variables.

The second cell values may be determined based at least in part on an algorithm, and the algorithm can have inputs including the first cell values and the second store values of the variables. The multiple variables can include k variables, and each of the k variables can have l possible store values. Each of the first store values and each of the second store values correspond to one of the l possible store values. Each of the n cells may have q possible cell states, and each of the n first cell values and each of the n second cell values can correspond to one of the q possible cell states. For a given set of values of k, l, n, and q, the algorithm can substantially maximize a minimum number of times that one or more of the k variables can be updated in the memory, under a constraint that, when updating one or more of the k variables in the memory, each of the n cells of the memory either remains in its previous cell state or progresses to a cell state higher than its previous cell state.

The algorithm may substantially allow any one of the k variables to be updated in the memory more times than any one of the k variables could be updated in the memory if the k variables were stored separately in the n cells, under a constraint that, when updating one or more of the k variables in the memory, each of the n cells of the memory either remains in its previous cell state or progresses to a cell state higher than its previous cell state.

The algorithm may allow one or more of the k variables to be updated in the memory at least a number of times specified by (n−1)(q−1)+(q−1)/2; (n−1)(q−1); (n−2)(q−1)+1; (n−6−2 log₂ n)(q−1)+2; 2(q−1); (n−4)(q−1)+2; (n−3)(q−1)+1; (n−6)(q−1)+3; (n−5)(q−1)+2; (n−10−2 log₂ n)(q−1)+4; or (n−17−6 log₂ n)(q−1)+6.

The memory may include multiple memory blocks, and each of the memory blocks can have multiple cells. A particular one of the memory blocks can include at least a portion of the cells to which the first and second cell values are written. An operation may be performed to lower the state of each cell of the particular memory block to the lowest cell state. The operation to lower the state of each cell of the particular memory block to the lowest cell state may be performed at some time after the store value of one or more of the multiple variables can no longer be updated under a condition that each of the n cells of the memory either remains in its previous cell state or progresses to a higher cell state.

Each of the multiple possible cell states may be defined by an amount of charge stored in one of the n cells of the memory. One or more cell values may be detected, and each of the one or more detected cell values can correspond to a cell state of a particular one of the n cells of the memory. Multiple valid collective cell states may be defined, and whether or not the one or more detected cell values corresponds to any one of the valid collective cell states may be identified. At least one of the one or more detected cell values may be changed to make the detected cell values correspond to one of the valid collective cell states.

The cell values may be divided into subsets, and each subset can represent one or more of the first store values. A subset of the variables can include an index identifying a subset of the cells allocated for storing a second subset of the variables. One or more of the store values may be identified based at least in part on a linear covering code. The memory may be included in a system with a processor. The memory may comprise at least one of an optically encoded memory, a flash memory, a hard drive of a computer, a write asymmetric memory, or a write once memory.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a diagram illustrating a computing system.

FIG. 2 is a diagram illustrating a memory system in accordance with some aspects of the present disclosure.

FIG. 3A is a graphical representation of a code construction in accordance with some aspects of the present disclosure.

FIGS. 3B-3G are diagrams illustrating example code constructions in accordance with some aspects of the present disclosure.

FIGS. 4A-4F are diagrams illustrating example code constructions in accordance with some aspects of the present disclosure.

FIG. 5 is a flow chart illustrating an example process for storing information in a memory in accordance with some aspects of the present disclosure.

FIG. 6 is a flow chart illustrating an example process for correcting errors in accordance with some aspects of the present disclosure.

FIG. 7 is a table listing mappings between variables and binary vectors in accordance with some aspects of the present disclosure.

FIG. 8 is a table listing characteristics of example code constructions in accordance with some aspects of the present disclosure.

Like reference symbols in the various drawings indicate like elements.

### DETAILED DESCRIPTION

A memory may include multiple memory cells for storing information, and each of the memory cells may be able to assume multiple possible cell states. A memory cell may be described in terms of its possible cell states (e.g. “0” and “1” for a binary cell) and the transitions among its possible states (e.g. “0 to 1” and “1 to 0”). In a write asymmetric memory, such as a flash memory or an optically encoded memory, a different resource “cost” may be associated with different transitions. For example, a write operation (e.g., a transition where charge is injected into a flash memory cell) may be performed at a relatively low cost in terms of the amount of time and processing resources needed to perform the write operation, the amount of wear on the memory, and the lack of an impact on other cells in the memory. On the other hand, an erase operation (e.g., a transition where charge is removed from a flash memory cell) may have a higher associated cost in terms of the need to erase an entire block of memory cells (e.g., due to the construction of at least some flash memories, which requires cells to be erased in blocks), the amount of time and processing resources needed to rewrite some or most of the information stored in the memory block (e.g., when only a portion of the cells need to be erased, while the data stored in other cells needs to be retained), and the corresponding wear on the memory from erasing and rewriting cells. This wear on the memory may include memory cell damage (i.e., a reduction in memory cell quality) associated with implementing a particular cell state transition. For example, in a flash memory, erasing a block of memory cells may reduce the quality of the memory cells (e.g., the ability to reliably control the charge level when erasing and writing to the cell), and the operational lifetime of a flash memory may be limited to a finite number (e.g. 10⁵) of erasures. Other types of memories may have additional or different costs associated with writing, rewriting, and erasing memory cells.

Techniques (e.g., a code construction) may be implemented to increase the number of times information may be rewritten in a write asymmetric memory with multilevel cells without having to erase the memory. The cost of rewriting information may therefore be reduced by increasing the number of rewrites implemented between erasures (i.e. in a single write/erase cycle). For example, one or more variables stored in a memory may be updated multiple times using only low-cost operations and without the use of high-cost operations (e.g. erasures). By using only low-cost operations to rewrite information to the memory, the effective memory speed may be increased. Furthermore, by allowing multiple (low-cost) information rewrite steps before each (high-cost) memory erasure, the number of memory rewrites allowed by the lifetime of a memory may be increased, enhancing the effective lifetime of the memory.

Information stored in memory may be formatted as multiple variables. For example, each variable may be a binary or hexadecimal value, an ASCII character, or any other representation of information. According to the present disclosure, the values of multiple variables may be stored jointly in the collective state of multiple memory cells. When storing values of multiple variables jointly in the collective state of memory cells, the state of any one of the individual cells may be based on the value of more than one of the variables. In some implementations, neither an individual memory cell nor a subset of memory cells is allocated for storing the value of a single variable. Rather, a group of memory cells are allocated for collectively storing the values of multiple variables. Storing information jointly may increase the number of times that one or more of the variables can be rewritten in the memory before erasure. For example, if the rewriting frequencies of the variables stored in a flash memory are non-uniform, jointly storing the variables in the collective state of multiple memory cells may increase the number of times that the most frequently rewritten variables can be updated in the memory before erasure (i.e., by increasing the charge stored in one or more cells without having to erase the cell). Thus, storing information jointly may reduce the number of memory erasures required for a given number of memory rewrites, which may extend the effective lifetime of the memory and/or increase the effective speed of the memory. Furthermore, the system 100 may implement one or more error-correction schemes concurrently with joint information storage.

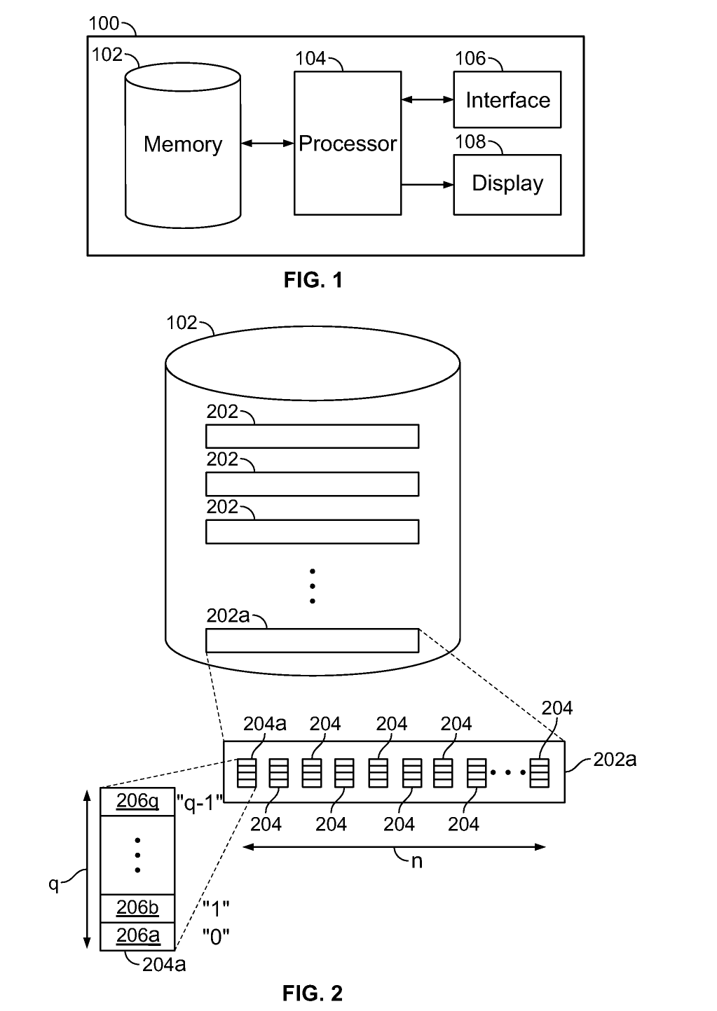

FIG. 1 is a diagram illustrating an example computing system 100. The computing system 100 includes a memory 102 in communication with a processor 104. The processor 104 may store information in the memory 102 and may retrieve information, such as software instructions and data, from the memory 102. The processor 104 may also communicate with an interface 106 and a display 108 for receiving input from a user and presenting information to a user.

FIG. 2 is a diagram illustrating an example implementation of the memory 102. The memory 102 may include multiple memory blocks 202, where each memory block 202 includes multiple memory cells 204. Each of the memory cells 204 may be in one of multiple possible cell states 206a, 206b, . . . 206q (collectively 206). Each state may be associated with a different sub-range of voltages within an overall range of voltages capable of being stored in each memory cell. The possible cell states 206 may be ordered sequentially from a lowest cell state (e.g. 206a), which may correspond to a stored charge within a relatively narrow sub-range near zero volts, to a highest cell state (e.g. 206q), which may correspond to a relatively narrow sub-range near a highest voltage used for storing data in the memory cells. Accordingly, each sequentially higher state may correspond to a progressively higher sub-range of voltages. In some implementations, each sub-range may be separated by some buffer zone of nominally unused voltages, which may help avoid reading incorrect values and facilitate error correction. The computing system 100 may allow information to be rewritten one or more times in the memory 102 using only operations that raise memory cells 204 from a lower cell state (e.g. 206a) to a higher cell state (e.g. 206b) and leave all other cells 204 in their previous cell states. By storing information jointly in the memory 102, the computing system 100 may increase the number of times that one or more variables can be updated in the memory 102 before erasure. For example, if two variables are stored jointly in four binary memory cells, it may be possible to rewrite either one of the two variables a minimum of three times before erasing the cells. The system 100 may implement algorithms for efficiently encoding and/or decoding information stored jointly in the memory 102; the algorithms implemented by the system 100 may also provide automatic error-correction.

The computing system 100 may include a variety of features not included in the illustration, such as memory buffers, electronic sensors and devices, transducers, adapters, communication ports, power supplies, and others. Generally, the computing system 100 may be any electronic or information processing device that uses nonvolatile memory, such as a portable or desktop computer, a calculator, a sensor, a server, a client, a personal digital assistant (PDA), a media player or recorder, a game console, a mobile phone, an email device and/or a monitoring device. The computing system 100 may also omit one or more of the illustrated features. For example, when the computing system 100 is implemented as a sensor, the display 108 and/or the interface 106 may be omitted. In some implementations, one or more of the components of the system 100 may be implemented as an external system. For example, the interface 106 may be an external data entry system (e.g a keyboard or an electronic sensor).

The memory 102 may be nonvolatile memory, such as read-only memory (ROM), optically encoded memory (e.g., CD, DVD, or LD), magnetic memory (e.g., hard disk drives, floppy disk drives), NAND flash memory, NOR flash memory, electrically-erasable, programmable read-only memory (EEPROM), ferroelectric random-access memory (FeRAM), magnetoresistive random-access memory (MRAM), non-volatile random-access memory (NVRAM), non-volatile static random-access memory (nvSRAM), phase-change memory (PRAM), punch cards, and/or any other memory that does not need its memory contents periodically refreshed and/or can retain information without power. The memory 102 may include memory chips or memory modules (e.g., single in-line memory modules (SIMMs) or dual in-line memory modules (DIMMs)). The memory 102 may be electrically, magnetically, or optically erasable. Part or all of the memory 102 may be removable (e.g. CD, flash memory stick) or non-removable (e.g. hard disk).

The processor 104 may include a programmable logic device, a microprocessor, or any other appropriate device for logically manipulating information. The processor 104 may execute an operating system for the computing system 100. The processor 104 may store information on or access information from the memory 102. Information may be stored or accessed, for example, by a user of the computing system 100, an application running on the computing system 100, or an external computing system connected to the computing system 100. The information may include multiple variables stored jointly in the memory 102. The processor 104 may send information to the display 108 (e.g. for presentation to a user). The processor 104 may communicate with the interface 104, for example, to transmit information to an external system, to receive information from an external system, and/or to receive information from a user. Information may be communicated to/from the processor 104 as electromagnetic and/or optical signals. Processor 104 may communicate with the memory 102, the interface 106, and/or the display 108 via local electronic circuitry (e.g. passive, active, resistive, conductive, capacitive, inductive, and/or semiconductor materials), wireless and/or wired network protocols (e.g., TCP/IP, Bluetooth, and/or Wi-Fi), and/or a bus (e.g., serial, parallel, USB, and/or FireWire).

The interface 106 may allow communication with external systems (e.g. external systems not illustrated in FIG. 1). Interface 106 may communicate with external systems via local electronic circuitry (e.g. passive, active, resistive, conductive, capacitive, inductive, and/or semiconductor materials), wireless and/or wired network protocols (e.g., TCP/IP, Bluetooth, and/or Wi-Fi) and/or a bus (e.g., serial, parallel, USB, and/or FireWire). The display 108 may present data such as text, videos, music, and/or other information from the processor 104 and/or the memory 102. For example, the display 108 may present data in visual and/or audio format. Other types of user interface devices may be used in addition to or instead of the display 108, such as a screen, speakers, and/or graphical or tactile interfaces.

As shown in FIG. 2, a memory cell 204 may generally have q possible cell states 206, where q may be any integer greater than or equal to two. A memory cell that can exist in one of q possible cell states may be referred to as a q-ary memory cell. The q possible cell states 206a, 206b, . . . 206q, may be selected based on physical (electronic, magnetic, mechanical and/or optical) properties of the cell 204 (e.g. electronic charge and/or threshold voltage) that can be reliably manipulated, maintained, and/or detected. For example, each of the possible cell states 206 for a flash memory may be defined as a specified amount of charge trapped in the cell 204; the state of the cell 204 may be manipulated by injecting charge into the cell 204 and may be detected by measuring the voltage or current of the cell 204 and comparing the measured voltage or current with various thresholds that correspond to the different cell states.

In some implementations, the sequential ordering of possible cell states 206 may be arbitrary. However, typically the sequential ordering of the possible cell states 206 may correspond to the order in which the cell 204 traverses the possible cell states 206 under the action of one or more of the operations available for manipulating the state of the memory cell 204. Continuing the example of the flash memory, the possible cell states 206 may be ordered sequentially according to the trapped charge specified by each state. For example, if an available memory operation includes injecting electrons into the cell 204, the lowest cell state (e.g. 206a) may be defined as the state that occurs when the cell 204 comprises the highest trapped charge (i.e. the fewest trapped electrons) and the highest cell state (e.g. 206q) may be defined as the state that occurs when the cell 204 comprises the least trapped charge (i.e. the most trapped electrons). Intermediate cell states (e.g. 206b, etc.) may be ordered sequentially (i.e. from lower cell states to higher cell states) in order of decreasing trapped charge (i.e. increasing number of trapped electrons). Alternatively, the possible cell states 206 may be sequentially ordered according to any other specification. For example, in some implementations, the possible cell states 206 may be ordered sequentially from the lowest cell state (e.g. 206a) to the highest cell state (e.g. 206q) in order of increasing trapped charge (i.e. decreasing number of trapped electrons), which may be useful for memories in which cells are erased by injecting electrons up to some threshold level and data is written by selectively removing electrons from the cell.

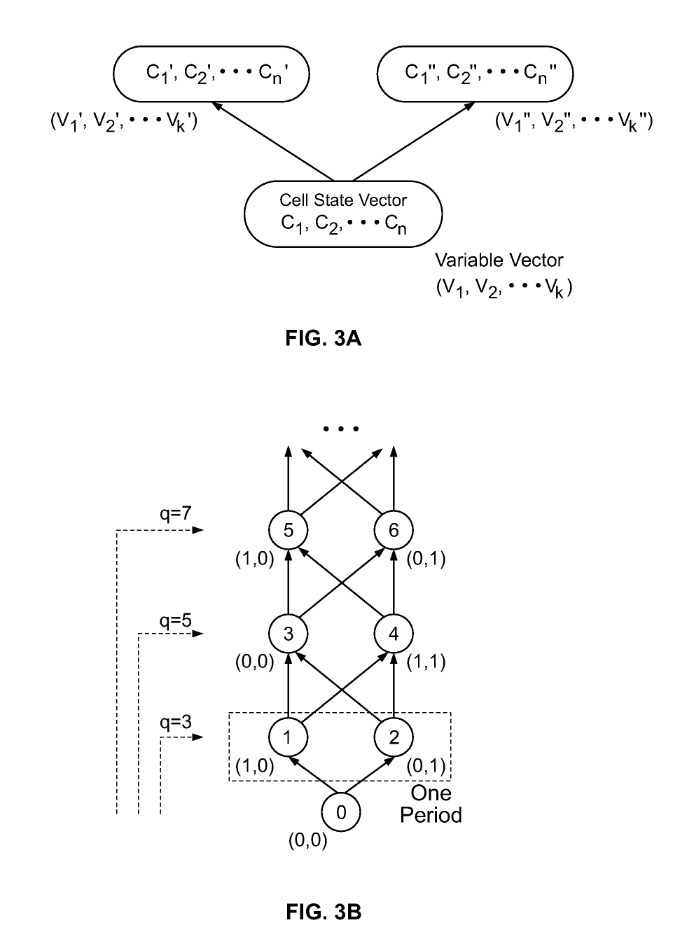

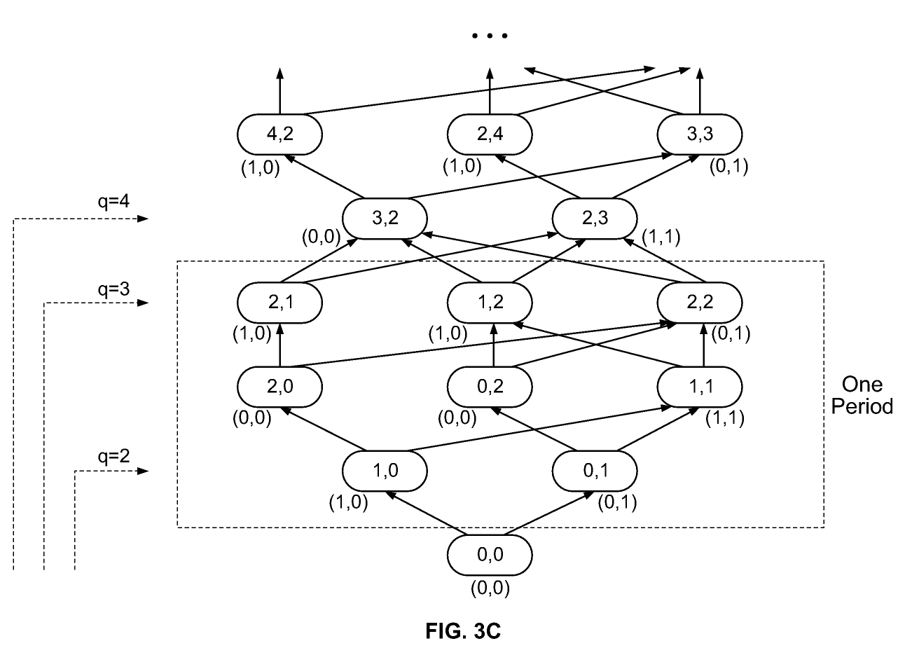

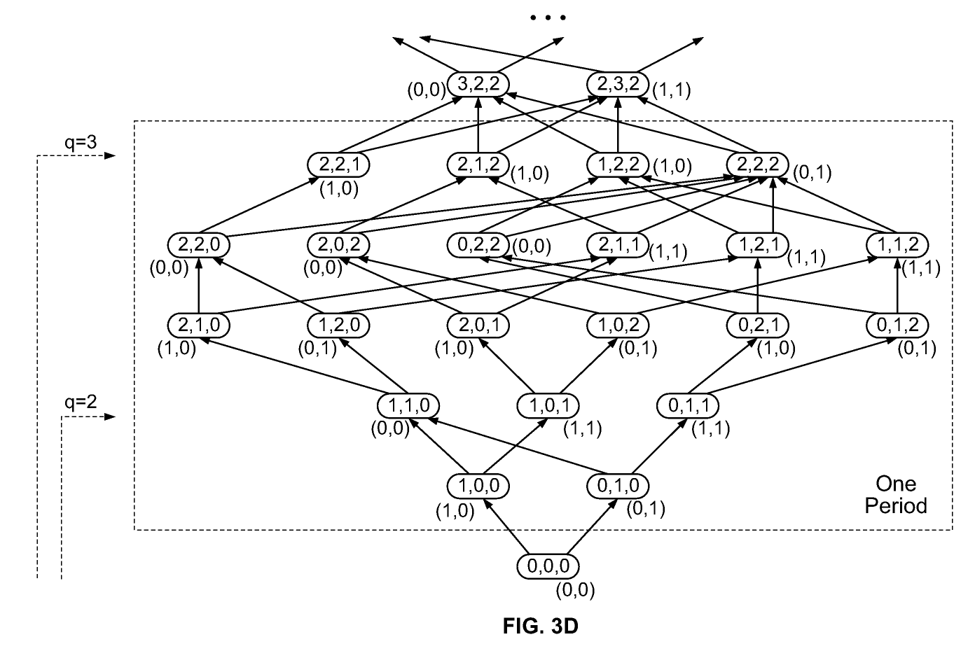

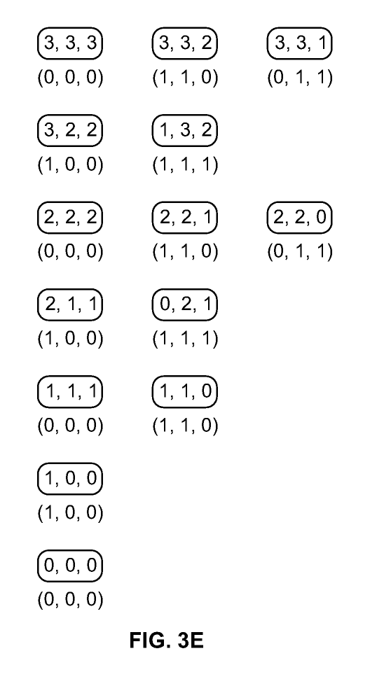

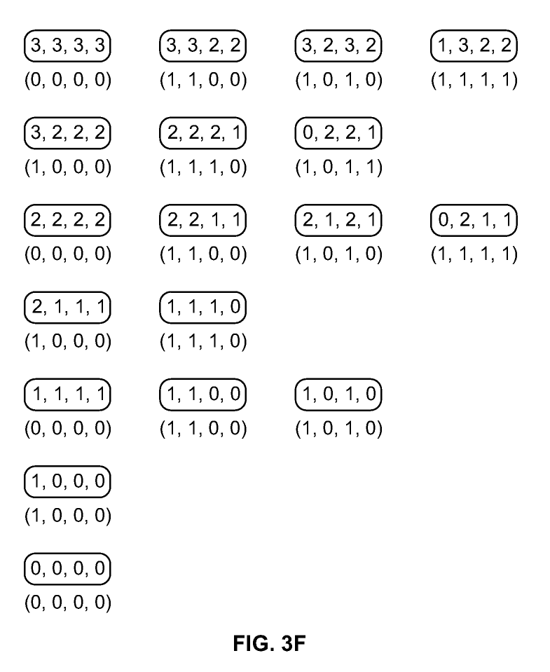

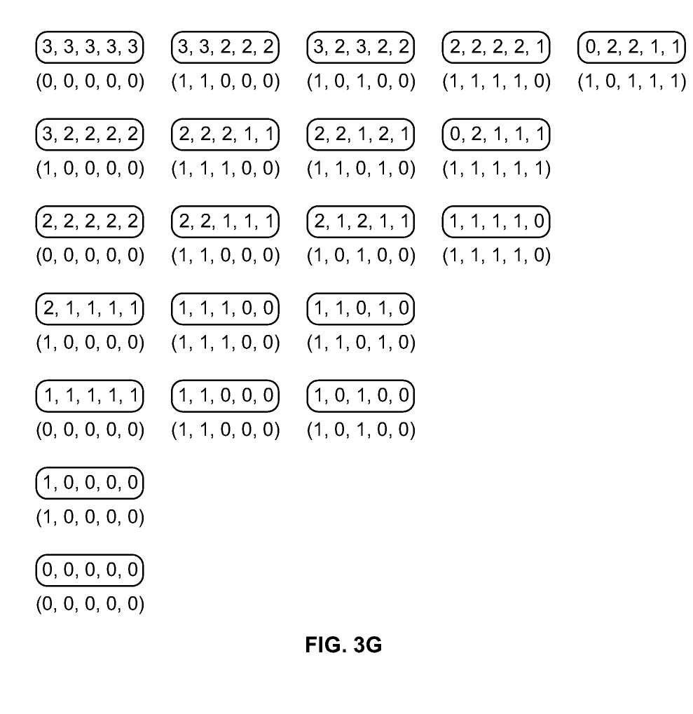

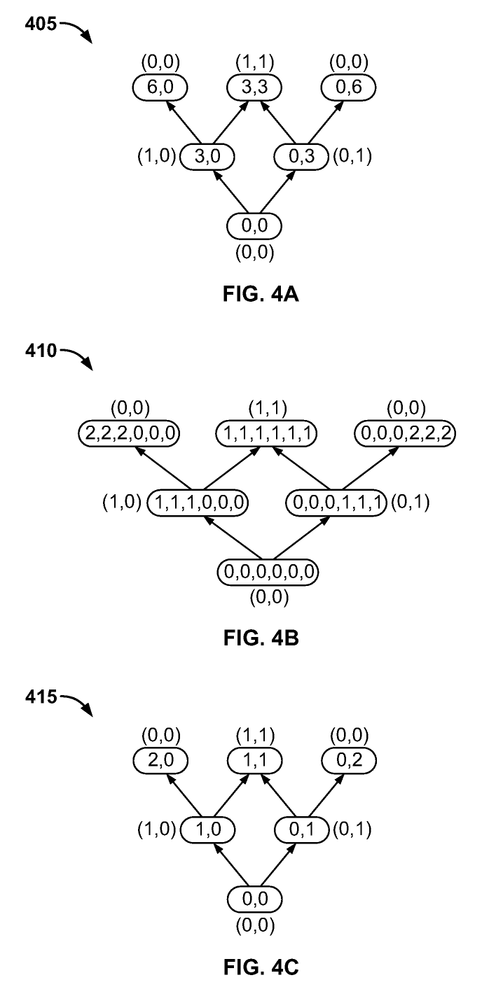

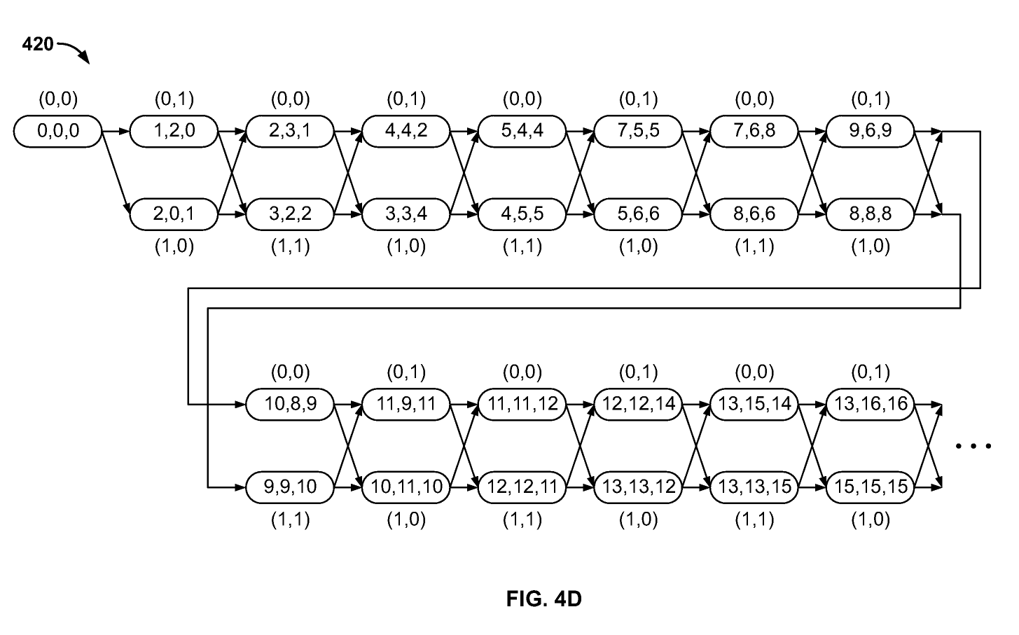

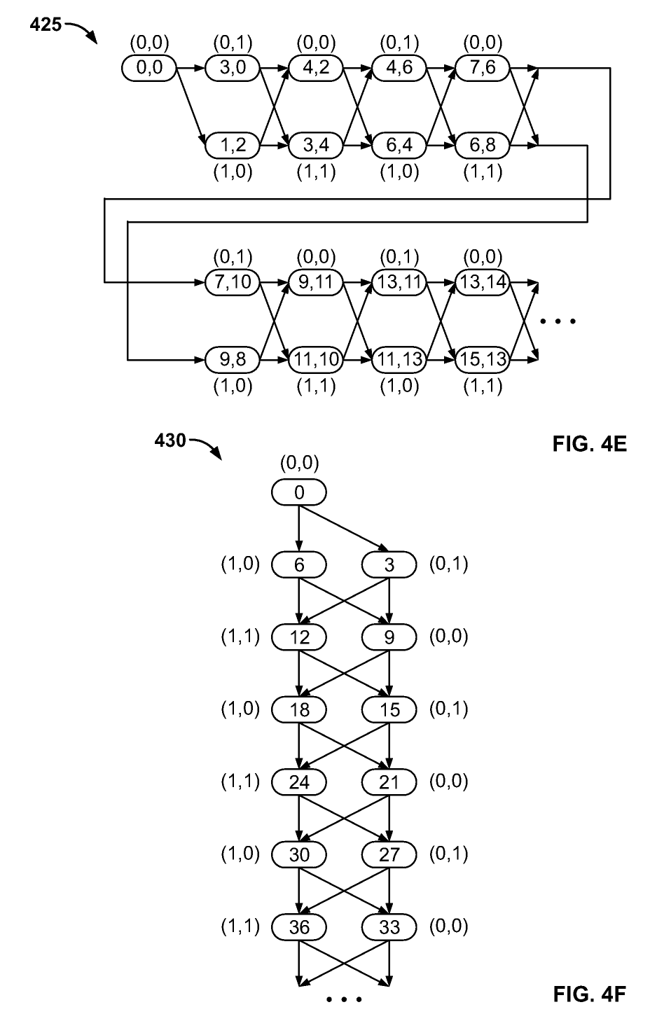

Each of the possible cell states (206a, 206b, etc.) may be labeled or associated with a cell value. For example, as illustrated in FIG. 2, the cell value “0” may designate the lowest cell state (e.g. 206a), the cell value “1” may designate the second lowest cell state (e.g. 206b), and the cell value “q−1” may designate the highest cell state (e.g. 206q). Other labeling schemes may also be used. For example, the cell value “0” may designate the highest cell state (e.g. 206q), the cell value “q−2” may designate the second lowest cell state (e.g. 206b), and the cell value “q−1” may designate the lowest cell state (e.g. 206a). For the purposes of the present disclosure, a cell state may be referred to by the cell value designating that state. For example, the cell state 206a may be referred to as the cell state “0.” In the examples provided in FIGS. 3A-3G and FIGS. 4A-4F, the lowest cell state is designated by the cell value “0” and the highest cell state is designated by the cell value “q−1.”

Erasing a memory cell 204 may include lowering the memory cell to its lowest cell state (e.g. the cell state “0”). In some implementations, memory cells 204 may not be individually erasable. For example, the operation for erasing the memory cell 204a may necessitate erasing all of the memory cells 204 of memory block 202a. In other implementations, the memory cells 204 may be individually erasable, and individually erasing a memory cell 204a may include a high-cost operation (i.e. an operation that uses more computational resources, such as time, energy, hardware, and/or hardware damage, than other operations). Therefore, reducing the number of memory erasures performed while using the memory 102 may improve the effective speed, efficiency, and/or operational lifetime of the memory 102.

Writing a cell value to a memory cell 204 may include performing operations that cause the memory cell 204 to assume the cell state designated by the cell value. For example, writing the cell value “1” to memory cell 204a may include raising the state of cell 204a from the lowest cell state 206a (designated by the cell value “0”) to the second lowest cell state 206b (designated by the cell value “1”). In some implementations, writing a cell value to a memory cell 204 may be done using low-cost operations (i.e. an operation that uses less computational resources, such as time, energy, hardware, and/or hardware damage, than other operations), such as raising the state of the memory cell 204 by injecting electrons into the cell 204. In some implementations, cell values may be written to the cells 204 of the memory 102, and new cell values may be rewritten to the cells 204 of the memory 102 before any of the memory cells 204 are erased (or new cell values may be rewritten to the a subset of the cells 204 of the memory 102 before any of the memory cells 204 in the subset are erased). A write/erase cycle may refer to the sequence of writing, rewriting (one or more times), and erasing cell values on one or more memory cells 204.

In some implementations, the operational lifetime of the memory 102 may be roughly bound by a finite number (e.g. 10⁵) of erasures (i.e. write/erase cycles). As the finite number of erasures approaches, the reliability of manipulating, maintaining, and/or detecting the state of a memory cell 204 may become reduced. At some, point, the reliability may render the memory cell 204 effectively or actually unusable because the memory may be incapable of storing data for an acceptable period of time and/or may require an unacceptable amount of error correction. For example, after a certain number of erasures of a flash memory cell, the flash memory cell may tend to leak electrons, impairing the ability of the flash memory cell to maintain a specified amount of charge. As another example, after a certain number of erasures, the ability to erase a flash memory cell (i.e. to remove some or all of the trapped electric charge) may be reduced. Therefore, increasing the number of times that information can be written to the memory 102 before the memory 102 is erased may increase the effective lifetime of the memory 102. The techniques described here may increase the number of times that information can be rewritten to the memory block 202 before the memory block 202 is erased.

The information stored in the memory 102 may include multiple variables. A variable may be a label representing one of a well-defined set (i.e., an alphabet) of possible values. The value (or store value) of a variable may be a particular one of the possible values represented by a variable in the memory 102. A variable, for example, may be an integer variable, a fixed point variable, a floating point variable, a single- or double-precision variable, or others. When the values of one or more variables are stored in a memory block 202a, the store values may be mapped to a corresponding set of cell values, and the cell values may be subsequently written to the memory cells 204 of the memory block 202a. For example, two variables v₁ and v₂ may have store values of 0 and 1, respectively. In a particular example, if the two variables v₁ and v₂ are to be jointly stored in the collective state of three memory cells, the store values 0, 1 may be mapped to the cell values 1, 0, 2. The cell values 1, 0, 2 may then be written to the three memory cells. Subsequently, the state of each memory cell 204 may be detected, and the cell values corresponding to the detected cell states may be used to recover the store values of the variables.

The mapping between cell values (which designate cell states) and store values (which designate values of variables) may be defined arbitrarily and stored, for example, as a table. In some implementations, the mapping between cell values and store values may be defined algorithmically, for example, by a code construction. A code construction may allow multiple variables to be stored jointly in a plurality of memory cells and may increase the number of times that one or more variables can be updated before the state of any one of the plurality of memory cells is lowered (e.g. by erasure). In some implementations, a code construction may include an algorithm that substantially maximizes, or otherwise provides a relative increase in, a minimum number of times that one or more variables can be updated in the memory 102 without erasing one or more of the memory cells 204, under a constraint that, when updating the variables in the memory, each of the memory cells 204 either remains in its previous cell state or progresses to a cell state higher than its previous cell state.

In some implementations, the n memory cells 204 may be divided into a plurality of subsets, and each subset may represent the store value of one or more variables. In some implementations, a code construction may dynamically allocate the subsets of memory cells 204. For example, if twenty memory cells are allocated to jointly store six variables, a code construction may divide the twenty memory cells into two or more cell groups (e.g. a “head part”, a “tail part”, a “middle part”, or a “team”). The code construction may divide the six variables into two or more groups of variables, and each group of variables may be allocated to a different one of the two or more cell groups. When one or more of the variables is updated in the memory, the division of memory cells and/or the division of variables may be changed, and/or the allocation of groups of variables to cell groups may be changed.

In some implementations, a code construction may allow any one of the variables stored jointly in the memory cells 204 to be updated more times than the maximum number of times than any one of the variables could be updated if the variables were stored separately in the same number of memory cells 204. For example, two variables may be stored in six memory cells 204 (i.e. n=6), where each variable comprises two possible values (e.g. 0 and 1) and each memory cell 204 comprises three possible cell states (i.e. q=3). In this example, a code construction that stores the two variables jointly may allow either one of the variables to be updated approximately 11 times under the constraint that, when updating the variables in the memory, each of the memory cells 204 either remains in its previous cell state or progresses to a cell state higher than its previous cell state. However, if the two variables are instead stored separately (i.e. not jointly), the maximum number of times that either one of the two variables could be updated (under the same constraint) may be 6 times or less. Storing variables separately may include storing each variable of the plurality of variables in a separate memory cell or subset of memory cells.

A number of example code constructions are described in the present disclosure and with regard to the figures. However, other code constructions and/or algorithms for storing information jointly in a memory and/or updating information stored jointly in a memory may also be used. Some of the concepts of the present disclosure are demonstrated in the examples, but the concepts of the present disclosure are not necessarily limited to the details of any of the examples.

In the context of the following examples, the values of k variables may be stored in a memory comprising n memory cells, where n may be a positive integer and k may be an integer greater than 1. According to various embodiments, k may be less than, equal to, or greater than n. Each of the n memory cells may include q possible cell states, ordered from a lowest cell state, designated by a cell value of “0,” to a highest cell state, designated by a cell value of “q−1”. Each of the k variables has an alphabet of size l: {0, 1, . . . l−1}, meaning that each of the k variables may be assigned one of I possible values. Both l and q may be integers, and both I and q may be greater than 1. A variable vector (e.g. (v₁, v₂, . . . vₖ) where vᵢε{0, 1, . . . l−1}) may represent the store values of each of the k variables. A cell state vector (e.g. (c₁, c₂, . . . cₙ) where cᵢε{0, 1, . . . q−1}) may represent the collective state of n memory cells. A cell state vector may include the cell values designating the state of each of the n memory cells. According to some implementations, a code construction may map a cell state vector to exactly one variable vector, and a code construction may map a variable vector to more than one cell state vector. A code construction may identify the particular cell state vector to be rewritten to the memory cells based on the current states of the memory cells in addition to the updated values of the variables to be stored. A code construction may be embodied as instructions (e.g. including rules, formulae, and/or tables) encoded on a tangible medium, such as the memory 102 of FIGS. 1 and 2, and executed by a processor, such as the processor 104 of FIG. 1.

FIG. 3A is a diagram illustrating a graphical representation of a code construction in accordance with some aspects of the present disclosure. The graphical convention used in FIG. 3A is used consistently through FIGS. 3B-3D and FIGS. 4A-4F. A value or set of values separated by commas and illustrated inside of a circle or oval shape indicates a cell state vector, and a value or set of values separated by commas and illustrated inside of parentheses indicates a variable vector. The variable vector corresponding to a given cell state vector (e.g. according to a code construction) is illustrated proximate to (typically below) the given cell state vector. As shown in FIG. 3A, the cell state vector (c₁, c₂, . . . cₙ) corresponds to the variable vector (v₁, v₂, . . . vₖ). In FIG. 3B, the cell state vector (c₁)=(3) corresponds to the variable vector (v₁, v₂)=(0, 0), and in FIG. 3D, the cell state vector (c₁, c₂, c₃)=(1, 0, 0) corresponds to the variable vector (v₁, v₂)=(1, 0).

In FIGS. 3A-3D and FIGS. 4A-4F, the arrows extending from a given cell state vector indicate how the memory may be rewritten when the memory cells are in the collective state represented by the given cell state vector. As shown in FIG. 3A, if the memory cells are currently in the collective cell state represented by the cell state vector (c₁, c₂, . . . cₙ), and if one or more of the variables is to be updated such that the updated variable vector is (v₁′, v₂′, . . . vₖ′), then the cell values (c₁′, c₂′, . . . cₙ′) may be written to the memory cells. As shown in FIG. 3D, if the memory cells are currently in the collective cell state represented by the cell state vector (1, 0, 0), and if the first variable (i.e. v₁) is to be updated to a store value of “0” (which means to change the variable vector from (1, 0) to (0, 0)), then the cell values (1, 1, 0) may be written to the memory cells. Similarly, if the sequence of updating the store values of the variables changes the variable vector as (0, 0)→(1, 0)→(1, 1)→(0, 1), then the cell state vector representing the collective state of the memory cells changes as (0, 0, 0)→(1, 0, 0)→(1, 0, 1)→(1, 0, 2).

The cell state vector (c₁′, c₂′, . . . cₙ′) may be referred to as “above” the cell state vector (c₁, c₂, . . . cₙ) if cᵢ′≧cᵢ for all i. (Similarly, the cell state vector (c₁, c₂, . . . cₙ) may be referred to as “below” the cell state vector (c₁′, c₂′, . . . cₙ′) under the same condition.) In some implementations, a code construction may use only operations that transit the n memory cells to a “higher” cell state vector. That is to say that the code construction may use operations only causing each of the n cells of the memory either to remain in its previous cell state (i.e. cᵢ′=cᵢ) or to progress to a cell state higher than its previous cell state (i.e. cᵢ′>cᵢ).

In some implementations, the store value of only one variable changes each time the k variables are updated (i.e. rewritten). Some code constructions may substantially optimize the number of times the k variables can be updated in the n memory cells before any of the memory cells has to be “lowered” (i.e. transited to a lower state or erased). In some implementations, for a given set of values of k, l, n, and q (that is to say, for a specified number k of variables to be stored on a specified number n of memory cells, where each of the k variables has a specified alphabet size l and each of the n memory cells has q possible states), a code construction may maximize, substantially maximize, or otherwise increase a minimum number of times that one or more of the k variables can be updated in the memory, under a constraint that, when updating one or more of the k variables in the memory, each of the n cells of the memory either remains in its previous cell state or progresses to a cell state higher than its previous cell state.

FIGS. 3B-3D are diagrams illustrating examples of a particular Code Construction (CC). CC is an algorithmic code construction for the case k=2, l=2, n>0, and q>1. FIG. 3B is a diagram illustrating CC for the case of n=1 (meaning that the k=2 variables are stored in the state of a single memory cell), and q=3, 5, and/or 7. FIG. 3C is a diagram illustrating CC for the case of n=2, q=2, 3, and/or 4. FIG. 3D is a diagram illustrating CC for the case of n=3, and q=2 and/or 3.

In all three examples (FIGS. 3B-3D), each memory cell begins in the lowest cell state, “0.” Each time one of the variables v₁ or v₂ is updated in the memory, the collective state of the memory cells progresses to a “higher” collective cell state. In some implementations, after one or more variables are updated one or more times, the memory block comprising the n memory cells may be erased. That is to say that each of the memory cells in the memory block may be lowered to the lowest cell state. In some implementations, the memory block is erased at some time after the store value of one or more of the plurality of variables can no longer be updated under a condition that each of the n cells of the memory either remains in its previous cell state or progresses to a higher cell state. Some code constructions may allow specification of a value t, the minimum number of times that any one or more of the k variables can be updated under a condition that each of the n cells of the memory begins in the lowest cell state and each of the n cells of the memory either remains in its previous cell state or progresses to a higher cell state upon each update.

The set of cell state vectors that may be written to the memory cells after i times of rewriting may be referred to as the i-th generation of cell state vectors. In FIGS. 3B-3D, cell state vectors in the same horizontal level may all be in the same generation. For example, in FIG. 3D, the cell state vectors in the 2nd generation are (1, 1, 0), (1, 0, 1), and (0, 1, 1). In FIGS. 3B-3D, a dotted box labeled “one period” indicates a periodic structure of the illustrated embodiments of the code CC. In the illustrated embodiments, the first generation in the dotted box includes two cell state vectors, each corresponding to a different variable vector. Similarly, the first generation above the dotted box includes two cell state vectors, each corresponding to a different variable vector. Additionally, the first generation above the dotted box can be obtained from the first generation in the dotted box by raising the state of each memory cell by two. For example, in FIG. 3C, the first generation inside the dotted box includes the cell state vectors (1, 0) and (0, 1). The first generation above the dotted box, which includes the cell state vectors (3,2) and (2,3), may be obtained by raising the state of each memory cell by 2.

The periodic structure indicated by the dotted box may be manifest in implementations of the code CC for arbitrarily large q. A “period” in the code CC may include 2n−1 generations. For example, in FIG. 3C, where n=2, a period in the code CC includes 3 generations. The second period may be generated from the first period according to the following specifications: (a) the state of each memory cell may be raised by 2 from the first generation to the second generation, (b) each occurrence of the variable vector (1, 0) in the first generation may be replaced with the variable vector (0, 0) in the second generation, (c) each occurrence of the variable vector (0, 0) in the first generation may be replaced with the variable vector (1, 0) in the second generation, (d) each occurrence of the variable vector (0, 1) in the first generation may be replaced with the variable vector (1, 1) in the second generation, (e) each occurrence of the variable vector (1, 1) in the first generation is replaced with the variable vector (0, 1) in the second generation.

For the examples of the code CC illustrated in FIGS. 3B-3D, the (2i+1)-th period (where i is a positive integer) may be generated from the first period by raising the state of each memory cell by 4i. Similarly, the (2i+2)-th period (where i is a positive integer) may be generated from the second period by raising the state of each memory cell by 4i. For finite values of q, the code CC may be obtained by generating the periodic structure of the code and truncating the structure below the first generation that includes a cell value greater than q−1. In some implementations, the memory may be erased after the memory cells reach a state represented by a cell state vector in the highest generation of the code.

Code Construction CC (k=2, l=2, n>0, q>1)

Generally, the Code Construction CC may be generated for any set of values satisfying k=2, l=2, n>0, and q>1, according to the following specifications:

(1.) For i=1, 2, . . . , n−1:

The i-th generation of cell state vectors may contain the i+1 cell state vectors that have the following properties: (1) among the first i+1 cell values in the cell state vector, i of them are “1” and one of them is “0,” and (2) the last n-(i+1) cell values in the cell state vector are “0.”

For a cell state vector in the i-th generation, if the first i cells values in the cell state vector are “1” and the last n−i cell values in the cell state vector are “0” (e.g., in the fourth generation, the cell state vector (1, 1, 1, 1, 0, 0)), then the cell state vector may correspond to either the variable vector (v1, v2)=(1, 0) for odd values of i or the variable vector (v1, v2)=(0, 0) for even values of i. Otherwise, the cell state vector in the i-th generation may correspond either to the variable vector (v1, v2)=(0, 1) (for odd values of i) or to the variable vector (v1, v2)=(1, 1) (for even values of i).

The cell state transitions for rewriting one of the variables may be specified as follows: from a cell state vector a in the (i−1)-th generation, (1) one arrow may go to the cell state vector in the i-th generation wherein the first i cell values are “1” and the last n−i cell values are “0,” and (2) the other arrow may go to the cell state vector of the i-th generation that is the same as cell state vector a except that its (i+1)-th cell value is “1” instead of “0.”

(2.) The (n−1)-th generation may include n cell state vectors, where each cell state vector includes n−1 cell values of “1” and one cell value of “0.” These n cell state vectors may be denoted as s₁, s₂, . . . sₙ. For the cell state vector sₘ (where 1≦m≦n), the n−1 memory cells in the cell state “1” may be denoted as b_{π(m,1)}, b_{π(m,2)}, . . . b_{π(m,n-1)}, and the memory cell in the cell state “0” may be denoted as b_{π(m,n)}, where (1≦π(m,j)≦n).

(3.) For i=n, n+1, . . . , 2n−3:

The n(i−n+2) cell state vectors in the i-th generation may be partitioned into n groups, where each group includes (i−n+2)=[i−(n−1)]+1 cell state vectors. For j=1, 2, . . . , n, the j-th group may include the [i−(n−1)]+1 cell state vectors that satisfy the following properties: (a) among the [i−(n−1)]+1 memory cells b_{π(j,1)}, b_{π(j,2)}, . . . , b_{π(j,[i-(n-1)]+1)}, i−(n−1) of them may be in the cell state “2” and one of them may be in the cell state “1,” (b) the 2n−i−3 memory cells b_{πj,i(n-1)+2)}, b_{π(j,i-(n-1)+3)}, . . . , b_{π(j,n-1)}, may be in the cell state “1”, (c) the memory cell b_{π(j, n)} may be in the cell state “0.”

In the i-th generation, for a cell state vector in the j-th group, if the memory cells b_{π(j,1)}, b_{π(j,2)}, . . . , b_{π(j,i-(n-1))} are in the cell state “2,” then the cell state vector may correspond to either the variable vector (v1, v2)=(1, 0) (for odd values of i) or the variable vector (v1, v2)=(0, 0) (for even values of i). Otherwise, the cell state vector in the j-th group of the i-th generation may correspond either to the variable vector (v1, v2)=(0, 1) (for odd values of i) or to the variable vector (v1, v2)=(1, 1) (for even values of i).

The cell state transitions for rewriting one of the variables may be specified as follows: from a cell state vector a in the (i−1)-th generation and in the j-th group (and if i−1=n−1, then a may denote the cell state vector sⱼ), (1) one arrow may go to the cell state vector in the i-th generation and the j-th group wherein the i−(n−1) cells b_{π(j,1)}, b_{π(j,2)}, . . . , b_{π(j,i-(n-1))} are in the cell state “2,” and (2) the other arrow may go to the cell state vector of the i-th generation and the j-th group that is the same as cell state vector a except that its cell b_{π(j,i-(n-1)+1)} is in the cell state “2” instead of “1”.

(4.) The (2n−3)-th generation may include n(n−1) cell state vectors, where each cell state vector has n−2 cell values of “2,” one cell value of “1,” and one cell value of

(5.) The (2n−2)-th generation of cell state vectors may contain n+[n!/(2!(n−2)!)] cell state vectors (where “!” denotes the factorial operation, wherein x!=(x)(x−1)(x−2) . . . (1)) which may be partitioned into two groups. The first group may contain the n cell state vectors wherein n−1 cell values are “2” and one cell value is “0.” The second group may contain all the n!/(2!(n−2)!) cell state vectors wherein n−2 cell values are “2” and two cell values are “1.” The cell state vectors in the first group may correspond to the variable vector (v₁, v₂)=(0, 0), and the cell state vectors in the second group may correspond to the variable vector (v₁, v₂)=(1, 1).

The (2n−1)th generation of cell state vectors may contain n+1 cell state vectors, which may be partitioned into two groups. The first group may contain the n cell state vectors where n−1 cell values “2” and one cell value is “1.” The second group may contain one cell state vector where the n cell values are “2.” The cell state vectors in the first group may correspond to the variable vector (v₁, v₂)=(1, 0); the cell state vector in the second group may correspond to the variable vector (v₁, v₂)=(0, 1).

Cell state transitions for rewriting one of the variables may be specified as follows: from a cell state vector a in the (2n−3)-th generation, (1) one of the outgoing arrows may enter the cell state vector of the (2n−2)-th generation in the first group that is “above” the cell state vector a, and (2) the other outgoing arrow may enter the cell state vector of the (2n−2)-th generation in the second group that is “above” the cell state vector a. Similarly, from a cell state vector a in the (2n−2)-th generation, (1) one of the outgoing arrows may enter the cell state vector of the (2n−1)-th generation in the first group that is “above” the cell state vector a, and (2) the other outgoing arrow may enter the cell state vector of the (2n−1)-th generation in the second group (which is “above” the cell state vector a).

(6.) The 2n−1 generations of cell state vectors described above with regard to items (1.) through (5.) may form the first period of the code CC. The second period of the code CC may be generated from the first period according to the following specifications: (a) the state of each memory cell may be raised by 2 from the first generation to the second generation, (b) each occurrence of the variable vector (1, 0) in the first generation may be replaced with the variable vector (0, 0) in the second generation, (c) each occurrence of the variable vector (0, 0) in the first generation may be replaced with the variable vector (1, 0) in the second generation, (d) each occurrence of the variable vector (0, 1) in the first generation may be replaced with the variable vector (1, 1) in the second generation, (e) each occurrence of the variable vector (1, 1) in the first generation may be replaced with the variable vector (0, 1) in the second generation.

The (2i+1)-th period, where i is a positive integer (e.g. 1, 2, 3, etc.), may be generated from the first period by raising the state of each memory cell by 4i. Similarly, the (2i+2)-th period, where i is a positive integer (e.g. 1, 2, 3, etc.) may be generated from the second period by raising the state of each memory cell by 4i. For finite values of q, the code CC may be obtained by generating the periodic structure of the code and truncating the structure below the first generation that includes a cell value greater than q−1.

Some implementations of the code CC may allow t to be approximately equal to (n−½)(q−1). In some implementations, it may be possible to specify an upper bound to the value of t. For example, if n≧k(l−1)−1, t may be less than or equal to [n−k(l−1)+1](q−1)+(½)(k(l−1)−(q−1); if n<k(l−1)−1, t may be less than or equal to (n/2)(q−1). In some implementations, the code CC may maximize the value of t, when values of k, l, n, and q are specified.

Code Construction CC-I (k=2, l=2, n>2, q>1)

A Code Construction CC-I may be generated for any set of values satisfying k=2, l=2, n>2, and q>1, according to the following specifications:

A valid cell state vector (c₁, c₂, . . . cₙ) may satisfy the following two conditions: (a) for 1≦i≦n and 1≦j≦n, |cᵢ−cⱼ|≦1, and (b) (c₁, c₂, . . . cₙ)=((a+1)^{x1}a^{x2}(a+1)^{x3}) for some values a, x₁, x₂, and x₃ that satisfy the three conditions: (b1) 0≦a<q−1, (b2) x₁+x₂+x₃=n, and (b3) x₂≧1. For example, when n=5, q=3, (1, 1, 1, 0, 1)=(1³ 0¹ 1¹) and (1, 1, 1, 1, 2)=(2⁰ 1⁴ 2¹) may both be valid cell state vectors.

A cell state vector ((a+1)^{x1}a^{x2}(a+1)^{x3}) may correspond to the variable vector (v₁, v₂) in the following way: v₁=odd(x₁), v₂=odd(x₃). The function odd(x) may have the property that odd(x)=1 for odd values of x, and odd(x)=0 otherwise. For example odd(7)=1, and odd(10)=0.

Updating one of the k=2 variables may proceed as follows: when updating the store value of variable v₁, if x₂ is not equal to 1, x₁ may be increased by 1 and x₂ may be decreased by 1; when updating the store value of variable v₂, if x₂ is not equal to 1, x₃ may be increased by 1 and x₂ may be decreased by 1. When x₂ is equal to 1, the state of each cell may be raised to the cell state designated by the cell value a+1 (which may make x₁=x₃=0 and x₂=0), then x₁ or x₃ (or both) may be increased accordingly. For example, for the code CC-I, in the case that k=2, l=2, n=4, and q=3, if the sequence of updating the store values of the k=2 variables changes the variable vector (v₁, v₂) as (0,0)→(0,1)→(0,0)→(1,0)→(1,1), then the cell state vector representing the collective state of the memory cells may change as (0, 0, 0, 0)→(0, 0, 0, 1)→(0, 0, 1, 1)→(1, 0, 1, 1)→(2, 1, 1, 2).

Some implementations of the code CC-I may allow t=(n−1)(q−1) for odd values of n and t=(n−2)(q−1)+1 for even values of n. In some implementations, it may be possible to specify an upper bound to t. Furthermore, the code CC-I may maximize t for the case of q=2.

Code Construction CC-II (k=3, l=2, n>4, q>1)

A Code Construction CC-II may be generated for any set of values satisfying k=3, l=2, n>4, and q>1, according to the following specifications:

A valid cell state vector (c₁, c₂, . . . cₙ) may satisfy the following two conditions: (a) for 1≦i≦n and 1≦j≦n, |cᵢ−cⱼ|≦1, and (b) the cell state vector may be in either Form I or Form II. Form I may be specified by ((a+1)^{x1}a^{x2}(a+1)^{x3}a^{x4}(a+1)x⁵) for some values a, x₁, x₂, x₃, x₄, and x₅ that satisfy the three conditions: (b1) x₁+x₂+x₃+x₄+x₅=n, (b2) x₂≧1, and (b3) x₄≧1. Form II may be specified by ((a+1)^{x1}a^{x2}(a+1)^{x5}) for some values a, x₁, x₂, and x₅ that satisfy the two conditions: (b4) x₁+x₂+x₅=n and (b5) x₂≧1. Both Form I and Form II satisfy the condition 0≦a<q−1.

A cell state vector may correspond to the variable vector (v₁, v₂, v₃) in the following way: (a) for a cell state vector in Form I: v₁=odd(x₁), v₂=odd(x₃), v₃=odd(x₅), and (b) for a cell state vector in Form II: v₁=odd(x₁), v₂=0, v₃=odd(x₅).

Updating one of the k=2 variables may proceed as follows: when updating the store value of variable v₁, if x₂ is not equal to 1, x₁ may be increased by 1 and x₂ may be decreased by 1; when updating the store value of variable v₃, if the cell state vector is in Form I and if x₄ is not equal to 1, x₅ may be increased by 1 and x₄ may be decreased by 1; when updating the store value of variable v₃, if the cell state vector is in Form II and if x₂ is not equal to 1, x₅ may be increased by 1 and x₂ may be decreased by 1; when updating the store value of variable v₂, if the cell state vector is in Form I, x₃ may be increased by 1 and either x₂ or x₄ may be decreased by 1; when updating the store value of variable v₂, if the cell state vector is in Form II, the cell value in the middle of the sequence of a's may be changed from state a to state a+1. If x₂ or x₄ is equal to one (i.e. x₂ and/or x₄ would become zero due to the above operation), the cell state vector may be reevaluated (i.e. by increasing x₁ and/or x₅, adjusting the cell state vector to represent the store values, and increasing x₂ and/or x₄ to a value greater than one), and the operation described above may be carried out again based on the store values of the variables. If the above operation cannot be carried out when the cells remain in the two states—state a and state a+1—then the two states a+1 and a+2 may be used in the same way as the two states a and a+1 have been used. Some implementations of the code CC-II may allow t greater than or equal to (n−6−2 log₂ n)(q−1)+2.

The code CC-II may be demonstrated by the following two examples (wherein n=10 and q=3): (Example 1) if the cell state vector representing the collective state of the memory cells is represented as (1¹ 0⁹ 1⁰), then the variable vector (v₁, v₂, v₃) may be expressed (1, 0, 0); if the sequence of updating the store values of the k=3 variables changes the variable state vector (v₁, v₂, v₃) as (1, 0, 0)→(0, 0, 0)→(0, 1, 0), then the cell state vector representing the collective state of the memory cells may change as (1¹ 0⁹ 1⁰)→(1² 0⁸ 1⁰)→(1² 0³ 1¹ 0⁴ 1⁰); (Example 2) if the cell state vector representing the collective state of the memory cells is represented as (1³ 0¹ 1¹ 0⁴ 1¹), then the variable vector (v₁, v₂, v₃) may be expressed (1, 1, 1); if the sequence of updating the store values of the k=3 variables changes the variable state vector (v₁, v₂, v₃) as (1, 1, 1)→(0, 1, 1)→(0, 1, 0), then the cell state vector representing the collective state of the memory cells may change as (1³ 0¹ 1¹ 0⁴ 1¹)→(1⁶ 0¹ 1¹ 0¹ 0¹)→(2⁰ 1⁴ 2¹ 1⁵ 2⁰).

Code Construction CC-III (k>2, l=2, n=k, q>1)

A Code Construction CC-III may be generated for any set of values satisfying k>2, l=2, n=k, q>1. The code may have a cyclic property: if the cell state vector (c₁=a₁, c₂=a₂, . . . , cₙ=aₙ) corresponds to the variable vector (v₁=b₁, v₂=b₂, . . . , vₙ=bₙ), then the cell state vector (c₁=a₂, c₂=a₃, . . . , cₙ₋₁=aₙ, cₙ=a₁) may correspond to the variable vector (v₁=b₂, v₂=b₃, . . . , vₙ₋₁=bₙ, vₙ=b₁). Three examples of the code CC-III for k=n=3, 4, and 5 are illustrated in FIGS. 3E, 3F, and 3G, respectively. Each generation of cell state vectors is only partially illustrated in FIGS. 3E-3G. In FIGS. 3E-3G (as in FIGS. 3A-3D) cell state vectors are illustrated in ovals, and variable vectors are illustrated in parentheses below their corresponding cell state vectors. Each full generation of cell state vectors (and corresponding variable vectors) for the code constructions illustrated in FIGS. 3E-3G may be derived based the cyclic property. For example, according to FIG. 3E (where k=3), the cell state vector (2, 1, 1) corresponds to the variable vector (1, 0, 0); so by the cyclic property, the cell state vector (1, 1, 2) may correspond to the variable vector (0, 0, 1), and the cell state vector (1, 2, 1) may correspond to the variable vector (0, 1, 0).

For any set of parameters satisfying n=k>2, l=2, and q>1, the code CC-III may allow t=2(q−1). Furthermore, the code CC-III may maximize t for the case of k=3. The code CC-III may be implemented according to the following specifications.

There may be four “Types” of valid cell state vectors, which may be labeled Type I, Type II, Type III, and Type IV. If all of the cell values in a cell state vector are equal (e.g. c₁=c₂= . . . =cₙ) the cell state vector may be of Type I, and the cell state vector may represent the variable vector having vᵢ=0 for i=1, 2, . . . , k. A value s may denote the lowest cell value in a cell state vector. If the greatest cell value in a cell state vector is equal to “s+1,” then the cell state vector may be of Type II, and the cell state vector may represent the variable vector having vᵢ=cᵢ−s for i=1, 2, . . . , k. If a cell state vector has the property that c₁=s, c₂=s+2, and cᵢ=s+1 for 2<i<n+1, then the cell state vector may be of Type III, and the cell state vector may represent the variable vector having v₁=1 for i=1, 2, . . . , k. If a cell state vector has the property that c₁=s, c₂=s+2, c₃=s+2, and cᵢ=s+1 for 3<i<n+1, then the cell state vector may be of Type IV, and the cell state vector may represent the variable vector with v₁=1, v₂=0, v₁=1 for i=3, 4, . . . , k. If a particular cell state vector C is a cyclic shift of a one of the cell state vectors D specified above (e.g. a cell state vector of Type I, II, III, or IV), then the cell state vector C may be of the same Type as the cell state vector D, and the cell state vector C may represent a variable vector that is a cyclic shift of the variable vector represented by the cell state vector D, following the cyclic property described above.

A valid cell state vector may have a corresponding layer number. After the memory cells have been rewritten A times, the state of the memory cells may correspond to a cell state vector having a layer number A. The layer number of a cell state vector may be computed as follows: (1) If a cell state vector is of Type I, its layer number may be 2c₁. (2) If a cell state vector is of Type II, a value X may denote the number of cells in the cell state vector who are in the highest cell state included in the cell state vector, a value s may denote the lowest cell state included in the cell state vector, and the layer number of the cell state vector may be 2s+X. (3) If a cell state vector is of Type III, a value s may denote the lowest cell state included in the cell state vector, and the layer number of the cell state vector may be 2s+n. (4) If a cell state vector is of Type IV, a value s may denote the smallest cell state in the cell state vector, and the layer number of the cell state vector may be 2s+n+1. When updating the store value of one or more of the variables, a value X may denote the layer number of the cell state vector before the update. A cell state vector Y in the layer number X+1 may represent the updated variable vector. Y may be identified using the code construction described above.

Code Construction CC-IV (k=3, l=2, n>4, q>1)

A Code Construction CC-IV may be generated for any set of values satisfying k=3, l=2, n>4, q>1. Code CC-IV is first described for an example where q=2. In this example, a cell state vector may include at least two cell values of “0,” and the second cell value of “0” (i.e. the “0” appearing second in the cell state vector) may split the n cell values of the cell state vector into two parts: the “head part” and the “tail part.” For example, for n=6, the cell state vector (0, 1, 0, 0, 0, 1) may be split into the head part (0, 1) and the tail part (0, 0, 1).

The head part may represent the two variables v₁ and v₂ according to the following specifications: (1) if, in the head part, there are an odd number of cell values of “1” and there is no cell value of “0” before a cell value of “1,” then (v₁, v₂) may be (1, 0), (2) if, in the head part, there are an odd number of cell values of “1” and there is one cell value of “0” before a cell value of “1,” then (v₁, v₂) may be (0, 1), (3) if, in the head part, there are an even number of cell values of “1” and there is no cell value of “0” before a cell value of “1,” then (v₁, v₂) may be (0, 0), (4) if, in the head part, there are an even number of cell values of “1” and there is one cell value of “0” before a cell value of “1,” then (v₁, v₂) may be (1, 1). The tail part may be used to represent the third variable v₃ according to the following specification: if, in the tail part, there are an even number of cell values of “1,” then v₃ may be 0; otherwise, v₃ may be 1. In some implementations, in the tail part, the cell values of “1” may be after the cells values of “0.”

An example of the code CC-IV is provided for the case where k=3, l=2, n=7, and q=2. When rewriting one of the k=3 variables causes the variable vector change as (0, 0, 0)→(0, 1, 0)→(0, 1, 1)→(1, 1, 1)→(1, 1, 0)→(0, 1, 0), then the cell state vector representing the collective state of the memory cells may change as (0, 0, 0, 0, 0, 0, 0)→(0, 1, 0, 0, 0, 0, 0)→(0, 1, 0, 0, 0, 0, 1)→(0, 1, 1, 0, 0, 0, 1)→(0, 1, 1, 0, 0, 1, 1)→(0, 1, 1, 1, 0, 1, 1). In some implementations, the head part and/or the tail part may grow longer as the variables are rewritten. For q=2, when the head part and the tail part meet (i.e. when there are only two cell values of “0”), the memory cells may be in a collective state represented by a cell state vector in the last generation of the code construction. For q>2, when the head and tail meet (i.e. when there are only two cell values of “0”), the code CC-IV may proceed to higher generations by using the cell states “2” and “1” as the cell states “1” and “0” are used in lower generations. Still higher generations may similarly use the cell states “j” and “j−1” as the cell states “1” and “0” are used in lower generations.

An example of the code CC-IV implementing higher generations for q>2 is provided for the case where k=3, l=2, n=7, and q=4. When rewriting one of the k=3 variables causes the variable vector change as (0, 0, 0)→(0, 1, 0)→(0, 1, 1)→(1, 1, 1)→(1, 1, 0)→(0, 1, 0)→(0, 1, 1)→(1, 1, 1), then the cell state vector representing the collective state of the memory cells may change as (0, 0, 0, 0, 0, 0, 0)→(0, 1, 0, 0, 0, 0, 0)→(0, 1, 0, 0, 0, 0, 1)→(0, 1, 1, 0, 0, 0, 1)→(0, 1, 1, 0, 0, 1, 1)→(0, 1, 1, 1, 0, 1, 1)→(1, 2, 1, 1, 1, 1, 2)→(1, 2, 2, 1, 1, 1, 2). In some implementations, the code CC-IV may allow t=(n−4)(q−1)+2 for even values of n and t=(n−3)(q−1)+1 for odd values of n.

Code Construction CC-V (k=4, l=2, n>6, q>1)

A Code Construction CC-V may be generated for any set of values satisfying k=4, l=2, n>6, q>1. The code CC-V may be generated in a similar manner as the code CC-IV is generated. However, for the code CC-V, the head part and the tail part may each be used to encode two variables. In some implementations, the code CC-V may allow t=(n−6)(q−1)+3 for even values of n and t=(n−5)(q−1)+2 for odd values of n.

Code Construction CC-VI (k=5, l=2, n>8, q>1)

A Code Construction CC-VI may be generated for any set of values satisfying k=5, l=2, n>8, q>1. The code CC-VI may be generated in a similar manner as the codes CC-IV and CC-V are generated. However, for the code CC-VI, a cell state vector may be split into three parts—a head part, a middle part, and a tail part. The head part and the tail part may each be used to represent two variables, and the middle part may be used to represent one variable. In some implementations, the code CC-VI may allow t to be greater than or equal to (n−10−2 log₂ n)(q−1)+4.

Code Construction CC-VII (k=6, l=2, n>11, q>1)

A Code Construction CC-VII may be generated for any set of values satisfying k=6, l=2, n>11, q>1. The code CC-VII may be generated in a similar manner as the codes CC-IV, CC-V, and CC-VI are generated. However, for the code CC-VII, the head part, the middle part, and tail part may each be used to represent two variables. In some implementations, the code CC-VII may allow t to be greater than or equal to (n−17−6 log₂ n)(q−1)+6.

Code Construction CC-VIII (k>1, l>1, n>0, q>1)

A Code Construction CC-VIII may be generated for any set of values satisfying k>1, l>1, n>0, q>1. The code CC-VIII may be described with respect to a particular example, where k=12, l=2, n=100, and q=6. However, the code CC-VIII is not limited to the details of the particular example. In the example, the k=12 variables may be partitioned into four groups: group G1 may be represented by the variable vector (v₁, v₂, v₃), group G2 may be represented by the variable vector (v₄, v₅, v₆), group G3 may be represented by the variable vector (v₇, v₈, v₉), group G4 may be represented by the variable vector (v₁₀, v₁₁, v₁₂). The n=100 memory cells may be partitioned into 10 teams, and each team may include ten memory cells: team T1 may be represented by the cell state vector (c₁, c₂, . . . , c₁₀), team T2 may be represented by the cell state vector (c₁₁, c₁₂, . . . , c₂₀), team T10 may be represented by the cell state vector (c₉₁, c₉₂, . . . , c₁₀₀), and teams T3 through T9 may similarly be represented by the appropriate cell state vectors. Generally, a team may include any appropriate number of memory cells, and in some implementations, the teams may not all include the same number of memory cells. For i=1, 2, 3, and 4, the cells of the team T1 may be used to store the variables of the group G1. For example, the group G1 may be stored in the team T1 according to a code construction, such as the code CC-IV for the case k=3.

Continuing the example, a code construction used to store the group G1 may allow a certain number of rewrites. For example, at some point (e.g. when the team T1 reaches a cell state vector in the highest generation of the code construction), it may no longer be possible to update one of the three variables of the group G1 under a condition that each of the ten cells of the team T1 either remains in its previous cell state or progresses to a higher cell state upon each update. In such a case, the group G1 may then be stored on a different team (e.g. T5). If the group G1 is to be stored in the team T5, two memory cells of the team T5 may be used as an index for remembering that the team T5 stores the group G1, and the index may be unchanged by subsequent rewrites of the variables of the group G1.

The code CC-VIII may progress as follows: every time a team of cells is fully used (e.g. the team reaches a cell state vector in the highest generation of the code construction), a different team may be used to store the group of variables, until all of the ten teams T1-T10 have been used. Two cells (e.g. the first two cells) of a team may be reserved as index cells.

The code CC-VIII may be generated for any set of parameters (k>1, l>1, n>0, q>1) according to the following specifications. The k variables may be divided into a groups: G1, G2, . . . , Ga. The n cells may be divided into b teams: T1, T2, . . . , Tb. In some implementations, b may be greater than or equal to a. First, group G1 may be stored in team T1 for i=1, 2, . . . , a, using an appropriate code construction (e.g. as shown in the above example). The code may progress as follows: every time a team of cells is fully used, the next un-used team may be used to store the group of variables, until all of the b teams have been used.

There may be many ways to record which team of cells is currently storing a particular group of variables. For example, index cells in each team of cells may be used, as described above. Alternatively, a specialized coding may be used, which may be described with respect to an example. In this example, there are 3 groups of variables G1, G2, G3 and 6 teams of cells T1, T2, T3, T4, T5, T6. Fully used teams may be differentiated from partially used teams and un-used teams by writing the highest cell value (“q−1”) to each cell in a fully used team. A partially used team or an u-used team may include at least one cell state in a state below “q−1.” Every group may be stored by one partially used team of cells, such that there are three partially used teams representing the three groups. The mapping between groups and team may be identified by a permutation (e.g. a permutation of length three). For example, when T1, T2 and T3 are partially used and they store G1, G2, G3 respectively, the permutation may be (1,2,3), which means that the first partially used team stores G1, the second partially used team stores G2, and the third partially used team stores G3. If, however, T2 becomes full and T4 is used to store G2, then the permutation may become (1,3,2), which means that the first partially used team T1 stores G1, the second partially used team T3 stores G3, and the third partially used team T4 stores G2. In some implementations, the three numbers in the permutation represent the order of the groups that are stored, respectively, by the first, second and third partially used teams. This approach may be generalized for any number of groups and teams.

The permutation may be recorded by a mapping from the permutation to multiple variables, and codes for jointly storing and rewriting multiple variables may be applied. This technique may be described with respect to the following example. If a permutation of three numbers (e.g. 1, 2, 3) is to be recorded, a mapping between the permutations and binary vectors (e.g. of length four) may be generated as follows: (1) the permutation (1, 2, 3) may be mapped to binary vectors (0, 0, 0, 0) and (0, 1, 1, 1); (2) the permutation (3, 1, 2) may be mapped to binary vectors (0, 0, 0, 1) and (0, 1, 1, 0); (3) the permutation (2, 3, 1) may be mapped to binary vectors (0, 0, 1, 0) and (0, 1, 0, 1); (4) the permutation (2, 1, 3) may be mapped to binary vectors (1, 0, 1, 0) and (1, 1, 0, 1); (5) the permutation (1, 3, 2) may be mapped to binary vectors (1, 0, 0, 0) and (1, 1, 1, 1); (6) the permutation (3, 2, 1) may be mapped to binary vectors (1, 0, 0, 1) and (1, 1, 1, 0). When the permutation changes (e.g. if an un-used team of cells becomes partially-used), only one bit in the vector may need to change. For example, if the permutation changes as (1, 2, 3)→(1, 3, 2)→(3, 2, 1)→(2, 1, 3)→(2, 3, 1), the binary vector may change as (0, 0, 0, 0)→(1, 0, 0, 0)→(1, 0, 0, 1)→(1, 1, 0, 1)→(0, 1, 0, 1). The binary vector may be stored as four variables (e.g. using a code construction), and the four variables may represent the permutation. This example may be generalized for permutations of different lengths.

The code CC-VIII may be used for any set of parameters (k>1, l>1, n>0, q>1). As n increases (e.g. as n approaches infinity), the code CC-VIII may asymptotically approach a maximum value of t. In the example given for the code CC-VIII, each of the ten teams may use two memory cells as index cells. However, the code CC-VIII may be implemented such that any number of cells may be used as index cells (e.g. in some implementations, a little more than one index cell is used per team, on average, by using the technique described by way of example with regard to CC-VIII).

Code Construction CC-IX (k>1, l>1, n>0, q>1)

A Code Construction CC-IX may be generated for any set of values satisfying k>1, l>1, n>0, q>1. The code CC-IX may be generated for cases where l>2 (e.g. based on a code construction where l=2). The code CC-IX may map a variable comprising a large alphabet (e.g. l=10) to a binary vector, such that when the variable changes its value, only one or a few of the binary values in the binary vector are changed. The code CC-IX may be described with respect to an example of the code CC-IX. However, the code CC-IX is not limited to the details of the particular example.

In an example of the code CC-IX, the variable v has an alphabet of size four (i.e. l=4 and vε{0, 1, 2, 3}), and the variable v may be mapped to a binary vector. For example, the binary vector may include three binary values (i.e. bits), and the binary vector may therefore comprise eight (2³=8) possible binary vector values. Each possible store value of the vector v may be mapped to one or more of the eight binary vector values. For example, v=0 may be mapped to the binary vector values (0, 0, 0) and (1, 1, 1), v=1 may be mapped to the binary vector values (1, 0, 0) and (0, 1, 1), v=2 may be mapped to the binary vector values (0, 1, 0) and (1, 0, 1), and v=3 may be mapped to the binary vector values (0, 0, 1) and (1, 1, 0). In this mapping, when the variable v changes its value, only one binary value in the binary vector may change its value. When rewriting the variable v changes the store value of the variable v as 0→1→2→0→3, then the binary vector value may change as (0, 0, 0)→(1, 0, 0)→(1, 0, 1)→(1, 1, 1)→(1, 1, 0).

In accordance with the code CC-IX, a variable may be mapped to a binary vector in a variety of ways (e.g. Hamming code, Golay code, and many others). A variable may also be mapped to a non-binary vector in a variety of ways (e.g. using non-binary covering codes). The following is a mapping method based on linear covering codes. A variable v may have an alphabet size l. A (n0, k0) linear covering code C may have an alphabet size l0 and covering radius R0. (For instance, (0,0,0) and (1,1,1) may be the codewords of a linear covering code having n0=3, k0=1, l0=2 and R0=1. The covering radius R0=1 may indicate that every binary vector of length three differs from either (0,0,0) or (1,1,1) in at most one bit.) The (n0, k0) linear covering code may have a number of cosets of its codewords. In some implementations, if the number of cosets is at least as large as l, the l values of v may be mapped to l cosets, with each value of v mapped to all the vectors in the corresponding coset. (For instance, in the above example, where l=4, the 4 values of v may be mapped to the four cosets of a linear covering code with n0=3, k0=1, l0=2 and R0=1.) Such a mapping using covering codes may have the property that when the variable v changes its value, at most R0 variables in its corresponding vector change their values.

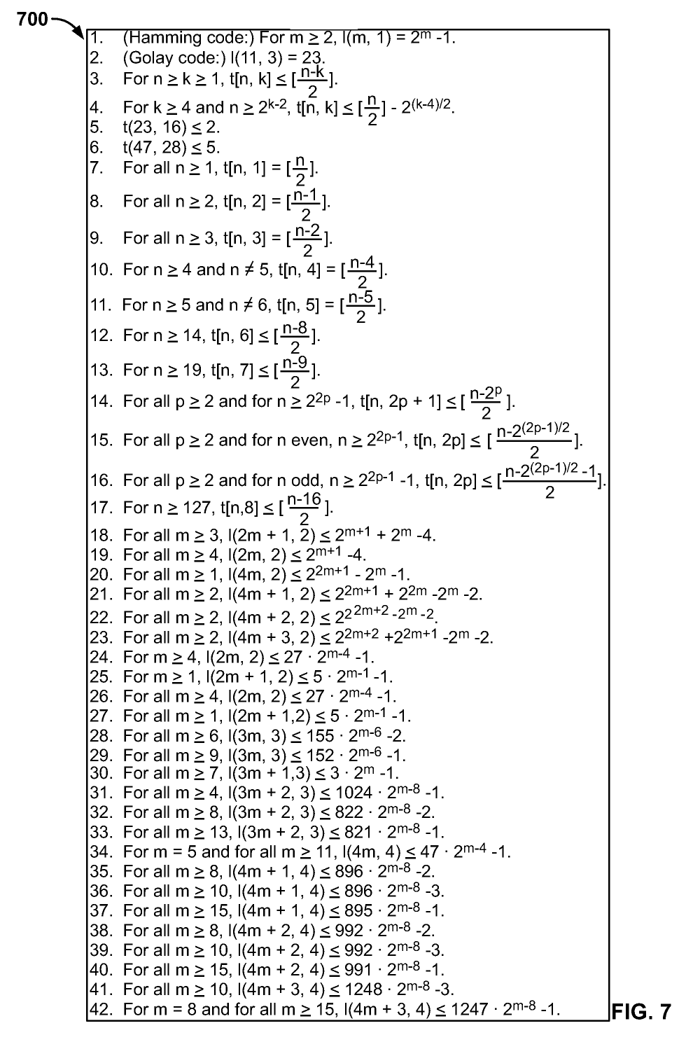

FIG. 7 is a table 700 listing example linear covering codes that may be used as mappings between variables and binary vectors. Continuing the example, the code CC-IX may be implemented for the case of n=20; q=5; k=2; l=4. The k=2 variables (v₁, v₂) may be mapped to a binary vector of having (3×2=) 6 binary values (i.e. a six bit binary vector). The binary vector may be represented as (a₁, a₂, a₃, b₁, b₂, b₃), where (a₁, a₂, a₃) is the binary vector representing the store value of the variable v₁ and (b₁, b₂, b₃) is the binary vector representing the store value of the variable v₂. A rewrite of (v₁, v₂) wherein either v₁ or v₂ changes (but not both) may correspond to a rewrite for (a₁, a₂, a₃, b₁, b₂, b₃) wherein only one of the six binary values changes. Therefore, a code construction for the case of n=20, q=5, k=6, l=2 (e.g. a particular case of the code CC-VII) may be converted to a code construction for the case of n=20, q=5, k=2, l=4. Moreover, if a code construction allows t=t₆ for the six variables (a₁, a₂, a₃, b₁, b₂, b₃), it may also allow t=t₆ for the two variables (v₁, v₂). The technique of mapping a code construction for l>2 to a code construction for l=2 or l=10 may be generalized to any appropriate set of parameters k, l, n, q. In this way, a code construction may be generated for general parameters.

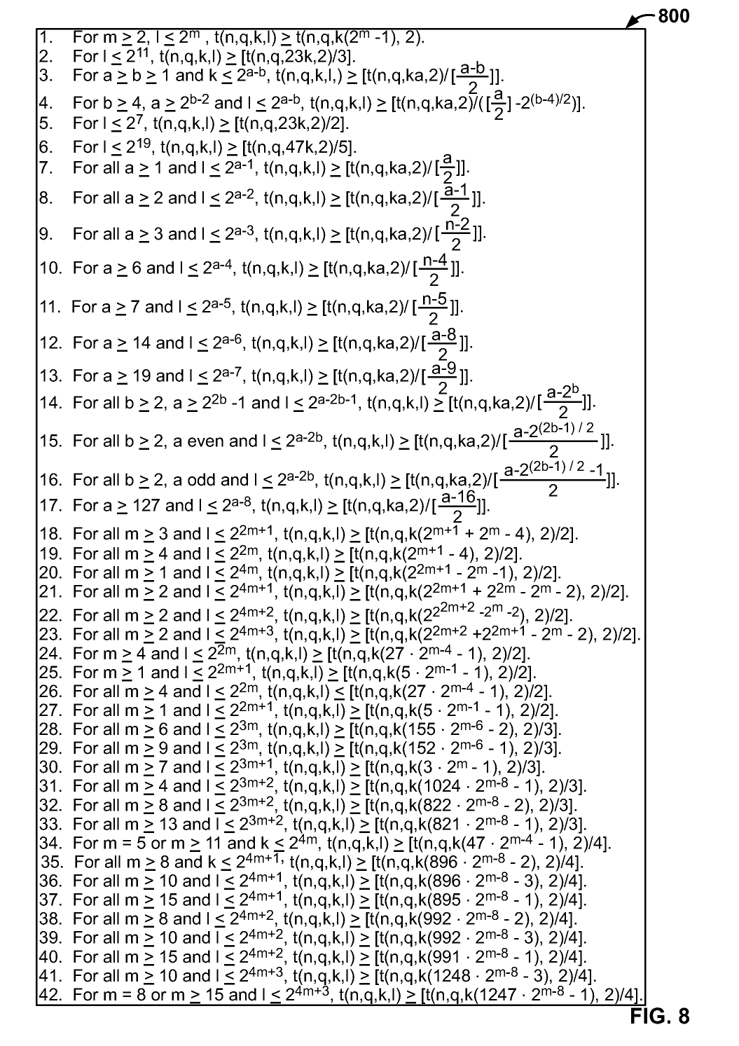

The maximum (i.e. optimal) value of t for a given code construction and a set of parameters k, l, n, and q, may be denoted t(n, q, k, l). Specification of a mapping between variables and binary or non-binary vectors, such as the mappings listed in table 700 of FIG. 7, may allow the specification of a relationship between a value of t(n, q, k, l) for a code construction with l>2 and a value of t(n, q, k, l) for a code construction with l=2 or l=10. FIG. 8 is a table 800 listing example relationships between t(n, q, k, l) for code constructions with l>2 and t(n, q, k, l) for code constructions with l=2. In particular, each line in table 800 of FIG. 8 corresponds to a line in table 700 of FIG. 7, and the relationship listed in a particular line of table 800 may be derived based on a code construction that uses the example mapping listed in the corresponding line in table 700.

FIGS. 4A-4F are diagrams illustrating example code constructions in accordance with some aspects of the present disclosure. FIGS. 4A, 4B, 4D, 4E, and 4F illustrate example error-correcting code constructions (ECCCs) in accordance with some aspects of the present disclosure. An ECCC may allow the correction of errors caused by noise and/or faults affecting the physical system in which information is stored and/or processed. An ECCC may also store and update information jointly in the collective state of multiple memory cells.

In some implementations, an ECCC is based on an error model having three parameters: Δ⁺, Δ⁻, and E. The parameter Δ⁺ may refer to the maximum magnitude of a single cell value error in the upward direction, Δ⁻ may refer to the maximum magnitude of a single cell value error in the downward direction, and E may refer to the maximum total magnitude of the cell value errors, such that E≧Δ⁺≧0 and E≧Δ⁻≧0. An error vector (e₁, e₂, . . . eₙ) may describe n additive errors affecting the n memory cells. For i=1, 2, . . . , n, the errors (e₁, e₂, . . . eₙ) may cause the cell state of the i-th cell, cᵢ, to be mistakenly read as the cell state designated by the cell value cᵢ+eᵢ. In some implementations, the errors may satisfy the following conditions: (1) Δ⁺≧eᵢ≧−Δ⁻ for all i=1, 2, . . . , n, and (2) Σᵢ₌₁ⁿ|eᵢ|≦E. The weight of a cell state vector (c₁, c₂, . . . cₙ) may refer to the sum of all cell values included in the cell state vector and may be calculated as Σᵢ₌₁ⁿcᵢ. The L₁ distance d_{L}(A, B) of two cell state vectors A=(c₁, c₂, . . . cₙ) and B=(c₁′, c₂′, . . . cₙ′) may refer to the quantity d_{L}(A, B)=Σᵢ₌₁ⁿ|cᵢ−cᵢ′|.

An ECCC may implement decoding and/or encoding. Encoding may occur when the ECCC maps every cell state vector (whether it contains errors or not) to a variable vector. In some implementations, it may be assumed that errors happen only when information is read from the memory. Such errors may be caused by faults or noise in a reading circuit. Under such an assumption, the actual states of the cells may be correct even when an error affects the readout. Decoding may occur when, given a cell state vector describing the current state of the memory cells and a new variable vector to store in memory (i.e. a variable vector including updated store values), the ECCC writes the cell values of a new cell state vector to the memory cells, where the new cell state vector corresponds to the new variable vector. In some implementation, an ECCC may be able to correct any error with parameters Δ⁺, Δ⁻, and E. For a given error model specification, an ECCC may allow a maximum or otherwise increased value of t while correcting for errors that are within the parameters of the error model specification. In other words, the value of t may be increased using the described techniques under a further constraint that the cell state vectors comply with the parameters of the error model.

The diagram conventions used in FIGS. 3A-3D are used consistently in FIGS. 4A-4F. An example ECCC 405 of FIG. 4A has the parameters k=2, l=2, n=2, q=7, and Δ⁺=Δ⁻=E=1, and may allow t=2. An example ECCC 410 of FIG. 4B has the parameters k=2, l=2, n=6, q=3, and Δ⁺=Δ⁻=E=1, and may allow t=2. The example code construction 415 of FIG. 4C, which is shown in order to demonstrate how an ECCC may be derived, has the parameters k=2, l=2, n=2, and q=3, and may allow t=2.

The ECCC 405 may be derived from the code construction 415 as follows: the cell value i in the ECCC 415 may be mapped to the cell value i·(Δ⁺+Δ⁻+1) in the ECCC 405. In this way, two valid states in the ECCC 405 may have a sufficiently large distance to allow error correction. The ECCC 410 may be derived from the code construction illustrated in FIG. 4C as follows: the state of each memory cell in the ECCC 415 may be mapped to 2E+1 memory cells in the ECCC 410. Repeating a cell state 2E+1 times may allow the correction of any E errors.

The ECCC 405 and the ECCC 410 can correct an error with parameters Δ⁺=Δ⁻=E=1. For example, referring to the ECCC 405, if the memory cells are in a collective state designated by the cell state vector (c₁=6, c₂=0), and the error vector is (e₁=−1, e₂=0), then the cell state vector may be incorrectly read as (c₁=5; c₂=0). Since, in the example, there is only one valid cell state vector within L₁ distance 1 from the cell state vector (5, 0), which is (6, 0), the cell state vector and the variable vector may be correctly decoded as (6, 0) and (0, 0), respectively.

The smallest distance of two valid cell state vectors in a code construction may be referred to as dₘᵢₙ. To form an ECCC, the following condition may be sufficient: dₘᵢₙ≧2E+1. To form an ECCC, the following condition may be necessary: dₘᵢₙ≧Δ⁺Δ⁻+1.

An ECCC 420, illustrated in FIG. 4D, has the parameters k=2, l=2, n=3, q>1, and Δ⁺=Δ⁻=E=1, and may allow t=q−2−(q/7). The ECCC 420 demonstrates a periodic pattern, where every period consists of six consecutive generations. To see the periodic pattern, observe the 2^{nd} generation of cell state vectors and the 8^{th} generation. The 2^{nd} generation includes the cell state vectors (c₁=2, c₂=3, c₃=1) and (c₁=3, c₂=2, c₃=2), while the 8^{th} generation includes (c₁′=10, c₂′=8, c₃′=9) and (c₁′=9, c₂′=9, c₃′=10). A mapping (M₁) shows a relationship between these two generations, M₁: c₁′=c₂+7, c₂′=c₃+7, c₃′=c₁+7. More generally, the mapping M₁ may continue for the i-th generation and the (i+6)-th generation, where i=2, 3, . . . 7.

In some implementations, the ECCC 420 may have the property that, for i=1, 2, . . . , 6 and j=0, 1, 2, 3, . . . , the mapping (M₁) continues for the (6j+i+1)-th generation and the (6(i+1)+i+1)-th generation. The ECCC 420 may, in principle, have infinitely many generations. When q is finite, the ECCC 420 may be truncated below the first generation including a cell value exceeding q−1. The ECCC 420 may correct any single cell value error of magnitude 1. The total number of valid cell state vectors in a code construction may be referred to as the code's cardinality. In some code constructions, the complexity of decoding may be related (e.g. proportional) to the cardinality of the code. The minimum cardinality for a code construction may be 2t+1. Among the codes with the cardinality 2t+1, the ECCC 420 may have a maximum value of t.

An ECCC 425 illustrated in FIG. 4E has the parameters k=2, l=2, n=2, q>1, and Δ⁺=Δ⁻=E=1, and may allow t=(4q−6)/7. An ECCC 430 illustrated in FIG. 4F has the parameters k=2, l=2, n=1, q>1, and Δ⁺=Δ⁻=E=1, and may allow t=(q−1)/6. The ECCC 425 has a periodic structure, where every period consists of four generations. To see the periodic structure, observe the 1^{st} generation of cell state vectors and the 5^{th} generation. The 1^{st} generation includes the cell state vectors (c₁=3, c₂=0) and (c₁=1, c₂′=2), while the 5th generation includes the cell state vectors (c₁′=7, c₂′=10) and (c₁′=9, c₂′=8). A mapping (M₂) shows a relationship between these two generations, M₂: c₁′=c₂+7, c₂′=c₁+7. More generally, for i=1, 2, 3, 4 and j=0, 1, 2, 3, . . . , the mapping M₂ may continue for the (4j+i)-th generation and the (4(j+1)+i)-th generation. A periodic structure of ECCC 425 may also be extended to higher generations by use of a similar mapping. Among the codes with the cardinality 2t+1, the ECCC 425 and the ECCC 430 may have a maximum value of t.

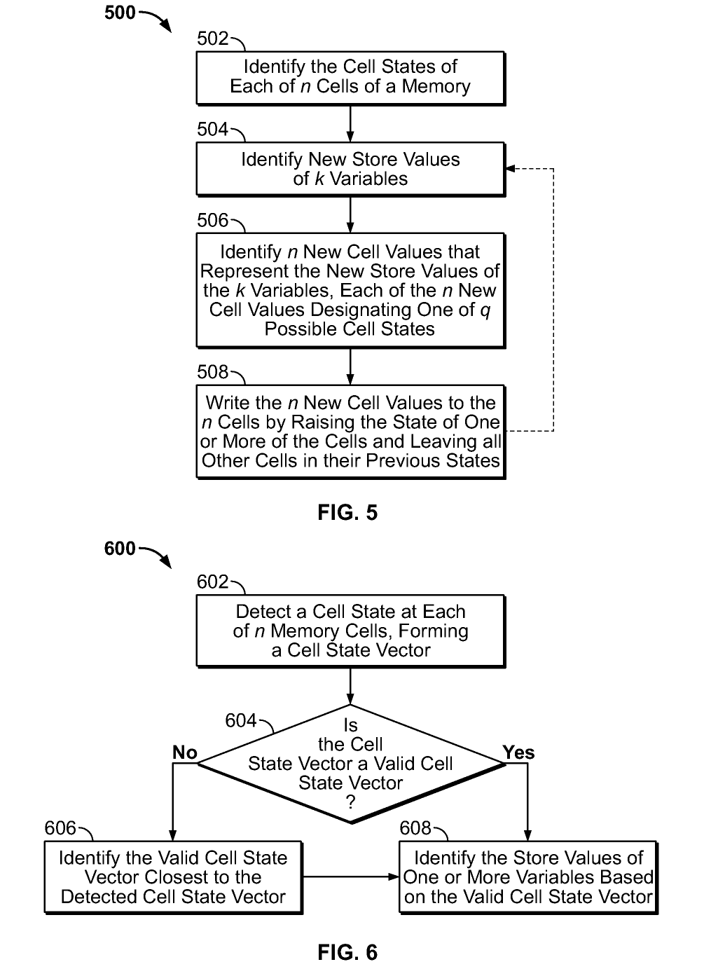

FIG. 5 is a flow chart illustrating an example process 500 for storing information in a memory. The process 500 may be used for storing and updating information in a memory. In particular, the process 500 may be used for storing and updating multiple variables jointly in the collective state of one or more cells of a memory. Additionally, the process 500 may be used to update information stored in memory cells using only operations that transit the memory cells to higher cell states and leave other memory cells in their previous cell states. The process 500 may be used for storing information in the memory 102 of FIG. 1.

At 502, cell states of n cells of a memory are identified. The memory may, for example, be the memory 102 of FIGS. 1 and 2. In some implementations, the memory may comprise any of an optically encoded memory, a flash memory, a hard drive of a computer, a write asymmetric memory, and/or a write once memory. A write once memory may include cells that only transit in one direction (e.g. to higher states or to lower states). For example, a punch card or an optically encoded memory may comprise a write once memory. The cell state of a cell may be identified, for example, by measuring the voltage of the cell at 502. A cell value corresponding to each of the identified cell states may also be identified. In some implementations, the cell state of each memory cell included in one or more memory blocks may be identified. Each of the n cells may comprise a plurality of possible cell states sequentially ordered from a lowest cell state to a highest cell state. At least one of the n identified cell states may be a cell state other than the lowest cell state. The n cell values designating the n identified cell states may jointly represent store values of a plurality of variables, such that at least one of the n cell values is individually based at least in part on the store values of more than one of the plurality of variables.

At 504, new store values of k variables are identified. In some implementations, only one of the k variables is updated, and only the new store value of the variable to be updated is identified. In some implementations, only a portion of the k variables are updated, and only the new store value of the portion of variables to be updated is identified. In other implementations, new store values of all k variables are identified.

At 506, n new cell values representing the new store values of the k variables are identified, where each of the n new cell values corresponds to one of q possible cell states. The q possible cell states may be defined, for example, as a specified amount of trapped charge in a cell. The possible cell states may be ordered sequentially from the lowest cell state to the highest cell state in order of increasing or decreasing trapped charge. In some implementations, each memory cell may comprise q=2 possible cell states, which may correspond to a binary system. In other implementations, each memory cell may comprise q>2 possible cell states.

In some implementations, the n new cell values are determined based at least in part on a code construction, and the code construction may include an algorithm having inputs comprising the n identified cell values (i.e. the n cell values identified at 502) and the new store values of the k variables.

In some implementations, each of the k variables comprises l possible store values, and each of the new (and previous) store values may designate one of the I possible store values. Writing the n new cell values to the n cells of the memory may comprise updating one or more of the k variables in the memory. In some implementations, for a given set of values of k, l, n, and q, an algorithm may substantially maximize a minimum number of times that one or more of the k variables can be updated in the memory, under a constraint that, when updating one or more of the k variables in the memory, each of the n cells of the memory either remains in its previous cell state or progresses to a cell state higher than its previous cell state.

At 508, the n new cell values are written to the n cells by raising the state of one or more of the cells and leaving all other cells in their previous cell states. A cell's previous cell state may, for example, be the state of the cell identified at 502. In some implementations, one or more of the k variables may be updated one or more times. Each time one or more of the k variables is updated, the process 500 may return to 504 and proceed. In some implementations, the process may implement 504, 506, and 508 as many times as it is possible (e.g. t times) to update one or more of the variables under the condition that, each time one or more of the variables is updated, none of the n cells is transited to a lower state. In some implementations, after one or more variables is updated, the memory cells may subsequently be erased or lowered to a lower cell state (e.g. the lowest cell state).

FIG. 6 is a flow chart illustrating an example process 600 for correcting errors. A memory, such as a flash memory, may be affected by faults or noise that change information stored in or extracted from the memory in a non-ideal manner. The changes caused by the noise may produce errors in the information stored in the memory. Generally, the process 600 may be used to correct errors in information stored in or extracted from a memory. More particularly, the process 600 may be used to correct errors in cell values representing cell states detected at one or more memory cells, such as the memory cells 204 of FIG. 2. In some implementations, the process 600 may correct errors caused by faults or noise in reading the memory 102 of FIG. 1.

At 602, a cell state is detected at each of n memory cells, and the cell values designating the detected cell states form a cell state vector. The detection process may be a noisy process that causes errors in the detected values. That is to say that one or more of the memory cells may be in a cell state other than the cell state detected. The n memory cells may jointly represent store values of a plurality of variables, such that at the cell state of least one of the n memory cells is individually based at least in part on the previous store values of more than one of the plurality of variables.

At 604, the cell state vector is compared to a set of valid cell state vectors in order to determine if the detected cell states form a valid cell state vector. The set of valid cell state vectors may be based on an error model. The error model may be based on physical phenomena (i.e. noise processes) known to cause errors in the memory; the error model may be based on observed errors that are known to affect the memory. The error model may include multiple parameters, such as a maximum magnitude of a single cell value error in the upward and/or downward direction, the maximum total magnitude of the cell value errors, the maximum number of cells with errors, and/or others.

In the case that the cell state vector is a valid cell state vector, then the store values of one or more variables stored in the n memory cells are identified (608) based on the valid cell state vector. The store values may be included in a variable vector, and a code construction may be used to map the valid cell state vector to the variable vector. If the memory (e.g. the memory read circuit) is affected by noise, the detected cell state vector may include an error, and the detected cell state vector may not be a valid cell state vector. In the case that the detected cell state vector is not a valid cell state vector, then the valid cell state vector closest to (i.e. having the least distance of) the detected cell state vector is identified (606), and (614) the store values of one or more variables stored in the n memory cells are identified based on the valid cell state vector. In some implementations, the valid cell state vectors may be the valid cell state vectors of an ECCC, and the ECCC may be used to identify the valid cell state vector when the detected cell state vector includes an error.

A number of embodiments of the invention have been described. Nevertheless, it will be understood that various modifications may be made without departing from the spirit and scope of the invention. For example, code constructions other than the examples described herein may be used to store and update information jointly in a memory. Furthermore, a code construction may implement additional, fewer, and/or different operations than the examples described herein, and a code construction may implement the operations in an order other than the order described in the examples. Accordingly, other embodiments are within the scope of the following claims.

What is claimed is:

1. A method comprising:
representing a plurality of variables with at least one cell value in a memory, wherein each variable is associated with one or more of the cell values and at least one single cell value influences a value of at least two of the variables; and
defining multiple states of the plurality of variables, wherein at least one of the multiple states of the plurality of variables is associated with more than one set of cell values.

2. A method comprising:
writing n first cell values to n cells of a memory, each of the n cells comprising a plurality of possible cell states sequentially ordered from a lowest cell state to a highest cell state, each of the n first cell values corresponding to one of the plurality of possible cell states, at least one of the n first cell values corresponding to a cell state other than the lowest cell state, the n first cell values jointly representing first store values of a plurality of variables, at least one of the n first cell values comprising an individual cell value based at least in part on the first store values of more than one of the plurality of variables; and
writing n second cell values to the n cells of the memory, each of the n second cell values corresponding to one of the plurality of possible cell states, each of the n cells of the memory either remaining in its previous cell state or progressing to a cell state higher than its previous cell state.

3. The method of claim 2, each of the n cells of the memory having two possible cell states, each of the n first cell values and each of the n second cell values corresponding to one of the two possible cell states.

4. The method of claim 2, each of the n cells comprising three or more possible cell states, each of the n first cell values and each of the n second cell values corresponding to one of the three or more possible cell states.

5. The method of claim 2, the n second cell values jointly representing second store values of the plurality of variables, wherein the second store value for at least one of the plurality of variables differs from the first store value for the variable, at least one of the n second cell values comprising an individual cell value based at least in part on the second store values of more than one of the plurality of variables.

6. The method of claim 5, the n second cell values determined based at least in part on an algorithm, the algorithm having inputs comprising the n first cell values and the second store values of the plurality of variables.

7. The method of claim 6, wherein:
the plurality of variables comprises k variables, each of the k variables comprising l possible store values, each of the first store values and each of the second store values corresponding to one of the l possible store values;
each of the n cells comprises q possible cell states, each of the n first cell values and each of the n second cell values corresponding to one of the q possible cell states; and
for a given set of values of k, l, n, and q, the algorithm substantially maximizes a minimum number of times that one or more of the k variables can be updated in the memory, under a constraint that, when updating one or more of the k variables in the memory, each of the n cells of the memory either remains in its previous cell state or progresses to a cell state higher than its previous cell state.

8. The method of claim 6, wherein:
the plurality of variables comprises k variables;
the algorithm substantially allows any one of the k variables to be updated in the memory more times than any one of the k variables could be updated in the memory if the k variables were stored separately in the n cells, under a constraint that, when updating one or more of the k variables in the memory, each of the n cells of the memory either remains in its previous cell state or progresses to a cell state higher than its previous cell state.

9. The method of claim 6, wherein:
the plurality of variables comprises k variables, each of the k variables comprising l possible store values, each of the first store values and each of the second store values corresponding to one of the l possible store values;
each of the n cells comprises q possible cell states, each of the n first cell values and each of the n second cell values corresponding to one of the q possible cell states; and
the algorithm allows one or more of the k variables to be updated in the memory at least a number of times comprising one of:
(n−1)(q−1)+(q−1)/2;
(n−1)(q−1);
(n−2)(q−1)+1;
(n−6−2 log₂ n)(q−1)+2;
2(q−1);
(n−4)(q−1)+2;
(n−3)(q−1)+1;
(n−6)(q−1)+3;
(n−5)(q−1)+2;
(n−10−2 log₂ n)(q−1)+4; or
(n−17−6 log₂ n)(q−1)+6.

10. The method of claim 2, the memory comprising a plurality of memory blocks, each of the memory blocks comprising a plurality of cells, a particular one of the memory blocks comprising at least a portion of the n cells, the method further comprising performing an operation to lower the state of each cell of the particular memory block to the lowest cell state.

11. The method of claim 10, wherein the operation to lower the state of each cell of the particular memory block to the lowest cell state is performed at some time after the store value of one or more of the plurality of variables can no longer be updated under a condition that each of the n cells of the memory either remains in its previous cell state or progresses to a higher cell state.

12. The method of claim 2, wherein each of the plurality of possible cell states is defined by an amount of charge stored in one of the n cells of the memory.

13. The method of claim 2, further comprising detecting one or more cell values, each of the one or more detected cell values corresponding to a cell state of a particular one of the n cells of the memory.

14. The method of claim 13, further comprising:
defining a plurality of valid collective cell states; and
identifying whether or not the one or more detected cell values corresponds to any one of the plurality of valid collective cell states.

15. The method of claim 13, further comprising:
defining a plurality of valid collective cell states; and
changing at least one of the one or more detected cell values to make the detected cell values correspond to one of the plurality of valid collective cell states.

16. The method of claim 2, wherein the n first cell values are divided into a plurality of subsets, each subset representing one or more of the first store values.

17. The method of claim 2, wherein a first subset of the plurality of variables comprises an index identifying a subset of the n cells allocated for storing a second subset of the plurality of variables.

18. The method of claim 2, wherein one or more of the store values is identified based at least in part on a linear covering code.

19. An article comprising a computer-readable medium storing instructions operable to cause data processing apparatus to perform operations comprising:
writing a first plurality of cell values to a plurality of cells of a memory, each of the plurality of cells comprising a plurality of possible cell states sequentially ordered from a lowest cell state to a highest cell state, each of the first plurality of cell values corresponding to one of the plurality of possible cell states, at least one of the first plurality of cell values corresponding to a cell state other than the lowest cell state, the first plurality of cell values jointly representing first store values of a plurality of variables, at least one of the first plurality of cell values comprising an individual cell value based at least in part on the first store values of more than one of the plurality of variables; and
writing a second plurality of cell values to the plurality of cells of the memory, each of the second plurality of cell values corresponding to one of the plurality of possible cell states, each of the plurality of cells of the memory either remaining in its previous cell state or progressing to a cell state higher than its previous cell state.

20. The article of claim 19, the second plurality of cell values jointly representing second store values of the plurality of variables, wherein the second store value for at least one of the plurality of variables differs from the first store value for the variable, at least one of the second plurality of cell values comprising an individual cell value based at least in part on the second store values of more than one of the plurality of variables.

21. The article of claim 19, the second plurality of cell values determined based at least in part on an algorithm, the algorithm having inputs comprising the first plurality of cell values and the second store values of the plurality of variables.

22. The article of claim 21:
the first plurality of cell values and the second plurality of cell values each comprising n cell values;
the plurality of cells comprising n cells;
the plurality of variables comprising k variables;
the algorithm substantially allowing any one of the k variables to be updated in the memory more times than any one of the k variables could be updated in the memory if the k variables were stored separately in the n cells, under a constraint that, when updating one or more of the k variables in the memory, each of the n cells of the memory either remains in its previous cell state or progresses to a cell state higher than its previous cell state.

23. A system comprising:
a memory comprising a plurality of cells, each of the plurality of cells comprising a plurality of possible cell states sequentially ordered from a lowest cell state to a highest cell state; and
a processor adapted to:
write a first plurality of cell values to the plurality of cells, each of the first plurality of cell values corresponding to one of the plurality of possible cell states, at least one of the first plurality of cell values corresponding to a cell state other than the lowest cell state, the first plurality of cell values jointly representing first store values of a plurality of variables, at least one of the first plurality of cell values comprising an individual cell value based at least in part on the first store values of more than one of the plurality of variables; and
write a second plurality of cell values to the plurality of cells of the memory, each of the second plurality of cell values corresponding to one of the plurality of possible cell states, each of the plurality of cells of the memory either remaining in its previous cell state or progressing to a cell state higher than its previous cell state.

24. The system of claim 23, the memory comprising at least one of an optically encoded memory, a flash memory, a hard drive of a computer, a write asymmetric memory, or a write once memory.

25. The system of claim 23, the memory comprising a plurality of memory blocks, each of the memory blocks comprising its own plurality of cells.

26. The system of claim 23, a particular one of the memory blocks comprising at least a portion of the plurality of cells, the processor further adapted to perform an operation to lower the state of each cell of the particular memory block to the lowest cell state at some time after at least one of the plurality of cells reaches the highest cell state.
